(19) United States
(12) Patent Application Publication
(10) Pub. No.: US 2024/0349626 A1
(43) Pub. Date: Oct. 17, 2024

(54) ADVANCED QUANTUM PROCESSING SYSTEMS AND METHODS FOR PERFORMING QUANTUM LOGIC OPERATIONS

(71) Applicant: SILICON QUANTUM COMPUTING PTY LIMITED, Kensington, New South Wales (AU)

(72) Inventors: Ludwik Kranz, Kensington, New South Wales (AU); Samuel Keith Gorman, New South Wales (AU); Md Serajum Monir, New South Wales (AU); Stephen Roche, New South Wales (AU); Daniel Keith, New South Wales (AU); Rajib Rahman, New South Wales (AU); Michelle Yvonne Simmons, New South Wales (AU)

(73) Assignee: SILICON QUANTUM COMPUTING PTY LIMITED, Kensington, New South Wales (AU)

(21) Appl. No.: 18/294,840

(22) PCT Filed: Aug. 2, 2022
(86) PCT No.: PCT/AU2022/050827

§ 371 Date: Feb. 2, 2024

(30) Foreign Application Priority Data
Aug. 2, 2021 (AU) 2021902381

(51) Int. Cl. H10N 60/10; G06N 10/40; H03K 17/92

(52) U.S. Cl. CPC H10N 60/11; G06N 10/40; H03K 17/92; H10N 60/128

(57) ABSTRACT

Quantum processing element and method to perform logic operations on a quantum processing element are disclosed. The quantum processing element includes: a semiconductor, a dielectric material forming an interface with the semiconductor, a plurality of dopant dots embedded in the semiconductor, each of the dopant dots comprising one or more dopant atoms and one or more electrons or holes confined within the dopant dots, wherein spin of an unpaired electron or hole of each dopant dot forms at least one qubit. The method includes the step of: controlling orientation of nuclear spins of the one or more dopant atoms in a pair of dopant dots and/or controlling a hyperfine interaction between nuclear spins of one or more dopant atoms and electron or hole spins of the unpaired electron or hole in the pair of dopant dots to perform a quantum logic operation on a corresponding pair of qubits.

### TECHNICAL FIELD

Aspects of the present disclosure are related to advanced processing systems and methods for operating the same and more particularly, to quantum processing systems which are controllable to perform quantum logic operations using quantum logic gates.

### BACKGROUND

The developments described in this section are known to the inventors. However, unless otherwise indicated, it should not be assumed that any of the developments described in this section qualify as prior art merely by virtue of their inclusion in this section, or that those developments are known to a person of ordinary skill in the art.

Large-scale quantum processing systems hold the promise of a technological revolution, with the prospect of solving problems, which are out of reach with classical machines. To date, a number of different structures, materials, and architectures have been proposed to implement quantum processing systems and fabricate their basic information units (quantum bits or qubits).

One way of fabricating qubits, for example, is to use the nuclear or the electron spin of phosphorus donor atoms in silicon such that the nuclear/electron spin of each phosphorus donor atom acts as a qubit. This fabrication technique offers near perfect qubit state encoding due to the addressability and long coherence of the phosphorus spins. Further, qubits fabricated in this manner have demonstrated second-long lifetimes and benefit from a semiconducting host enabling electrical addressing and high fidelities.

To start seeing the computational advantage that quantum processing systems can offer, however, basic quantum logic circuits (or quantum logic gates) need to be fabricated—which is not easy.

### SUMMARY

According to a first aspect of the present disclosure there is provided a method of operation of a quantum processing element. The quantum processing element comprising: a semiconductor, a dielectric material forming an interface with the semiconductor, a plurality of dopant dots embedded in the semiconductor, each of the dopant dots comprising one or more dopant atoms and one or more electrons or holes confined within the dopant dots, wherein spin of an unpaired electron or hole of each dopant dot forms at least one qubit. The method comprising the step of: controlling orientation of nuclear spins of the one or more dopant atoms in a pair of dopant dots and/or controlling a hyperfine interaction between nuclear spins of one or more dopant atoms and electron or hole spins of the unpaired electron or hole in the pair of dopant dots to perform a quantum logic operation on a corresponding pair of qubits.

In some embodiments, the pair of the qubits are used to perform a controlled ROT (CROT) gate and a controlled PHASE (CPHASE) gate and controlling the orientation of the nuclear spins comprising controlling the orientation of the nuclear spins to maximize the energy difference between the qubits. In order to do so, the nuclear spins in one dopant dot are oriented anti-parallel to the nuclear spins in the other dopant dot of the pair of dopant dots in some embodiments. In other embodiments, to maximize the energy difference between the qubits, at least one of the pair of dopant dots includes a plurality of dopant atoms, and the plurality of dopant atoms are positioned within the corresponding dopant dot such that the probability density of the wavefunction of the confined electrons or holes at these atomic sites is maximized.

In other embodiments, the pair of dopant dots are used to perform a SWAP^{α} gate, where α is between 0-4π and wherein controlling the orientation of the nuclear spins of the one or more dopant atoms in the pair of dopant dots comprising minimizing the energy difference between the qubits.

According to a second aspect of the present disclosure there is a provided a quantum processing element comprising: a semiconductor, a dielectric material forming an interface with the semiconductor, a plurality of dopant dots embedded in the semiconductor, each dopant dot comprising one or more donor or acceptor atoms and one or more electrons or holes confined within the corresponding dopant dots, wherein spin of an unpaired electron or hole of each of the dopant dots forms a qubit, wherein to perform a quantum logic operation between at least a pair of the qubits, an orientation of nuclear spins of the one or more dopant atoms in the at least pair of dopant dots is controlled.

Further, in some embodiments, at least one of the dopant dots in the pair of the dopant dots may include multiple donor or acceptor atoms. In addition, in some embodiments at least one of the dopant dots in the pair of the dopant dots includes multiple electrons or holes.

In such cases, the energy difference between the qubits may be minimized by orienting the nuclear spins in each of the dopant dots in a manner that minimizes the energy difference between the qubits.

In some embodiments, the fidelity of the logic gate operation performed on the at least pair of qubits can be increased by controlling a hyperfine interaction between the nuclear spins of the one or more dopant atoms and electron or hole spins of the unpaired electron or hole in the at least pair of dopant dots.

In such cases, controlling the hyperfine interaction includes at least one of: changing a number of dopant atoms in the dopant dots, arranging the dopant atoms within a dopant dot, controlling the number of electrons or holes in a dopant dot, controlling the background electrical field applied to the quantum processing element. In one example, the hyperfine interaction is controlled to maximize the energy difference between the pair of qubits by shielding the nuclear spins of the pair of dopant dots and adding multiple electrons or holes to each of the pair of dopant dots.

The donor atoms in the quantum processing element may be phosphorus atoms. Further, different gate operations can be performed on the pair of qubits by dynamically controlling the nuclear spins to create an optimal energy difference between the pair of qubits.

### BRIEF DESCRIPTION OF DRAWINGS

While the invention is amenable to various modifications and alternative forms, specific embodiments are shown by way of example in the drawings and are described in detail. It should be understood, however, that the drawings and detailed description are not intended to limit the invention to the particular form disclosed. The intention is to cover all modifications, equivalents, and alternatives falling within the spirit and scope of the present invention as defined by the appended claims.

FIG. 1 is a schematic illustrating a quantum dot based electron spin two-qubit device where a magnetic field gradient is generated by a micromagnet on the device.

FIG. 2 is a schematic illustrating a silicon-silicon dioxide interface device with g-factor variations due to surface roughness.

FIG. 3A is a schematic diagram of a quantum device including donor-bound electron spins experiencing local hyperfine fields.

FIG. 3B is a Scanning Tunnelling Microscopy (STM) micrograph of a two-qubit quantum device according to aspects of the present disclosure.

FIG. 3C is an STM image of the qubit sites of the quantum device of FIG. 3B.

FIG. 3D is an STM image of the left qubit of FIG. 3B.

FIG. 3E is an STM image of the right qubit of FIG. 3B.

FIG. 4 shows the impact of electric field applied parallel to a 2P axis and the impact of electric field applied at an angle to the 2P axis on the transition energies of qubits hosted on a 2P donor dot.

FIG. 5 is an energy diagram of a two-electron system.

FIG. 6A-6B are energy level diagrams of a 1P-1P and 1P-2P qubit pairs, respectively.

FIG. 6C is a diagram showing transition energy difference, ΔE_{z} between two qubits in the 1P-1P and 1P-2P system.

FIG. 6D is a Bloch sphere representation of a two electron spin system.

FIGS. 7A-7B show the ESR spectra of exchange-coupled electron spins hosted on 1P-1P and 1P-2P qubit pairs, respectively, with the left qubit nuclear spin initialized in the spin down state and the right qubit nuclear spin(s) initialized in the spin up state.

FIGS. 8A-8B show the CNOT gate errors plotted as a function of detuning and ESR frequency for a 1P-1P qubit pair and a 1P-2P qubit pair, respectively.

FIG. 9A shows a range of hyperfine energies for 1P, 2P and 3P donor qubits in different donor dot configurations.

FIG. 9B shows the CNOT gate error as a function of ΔE_{z} and the CNOT gate time.

FIG. 9C is a plot showing the impact of charge noise on the CNOT gate fidelity.

FIGS. 10A and 10B show several atomic configurations of a 3P and 2P qubit respectively along with their corresponding hyperfine values.

FIG. 10C shows ΔE_{z} values arising from different configurations of nuclear spins in a 3P-2P qubit pair.

FIG. 10D is a plot showing all 32 ΔE_{z} values for a 3P-2P qubit pair.

FIG. 10E shows a histogram of ΔE_{z} values.

FIG. 11A shows 12 plots of theoretically modelled exchange oscillations between two electron spins hosted on 3P and 2P donor dots.

FIG. 11B shows the configuration of the donor atoms in the 3P and 2P donor dots and their corresponding hyperfine values.

FIG. 11C shows all possible configurations of nuclear spins in the 3P-3P system of FIG. 11B.

FIG. 11D is a plot of a theoretically computed FFT signal of the exchange oscillations averaged over all possible configurations of nuclear spins (with equal probabilities).

FIG. 11E is a plot showing experimentally computed FFT spectrum of the exchange oscillations.

FIG. 11F is a chart showing experimental data from FIG. 11E and theory prediction from FIG. 11D presented in the time domain.

FIG. 11G is a schematic charge stability map showing the experimental protocol used for exchange oscillations.

FIG. 12 is an illustrative representation showing the impact of quantized ΔE_{z} values on coherent exchange oscillations in a SWAP gate.

FIG. 13 shows two-spin probabilities as a function of time, taken for donor device with the left and right donor dots comprising of 3P and 2P donors, respectively. In FIG. 13A, both donor dots include a single electron. In FIG. 13B, the left donor dot includes 1 electron and the right donor dot includes three electrons.

FIG. 14 shows examples of donor qubit pairs, with possible nuclear spin orientations and corresponding ΔE_{Z} values. In particular, FIG. 14A shows possible nuclear spin orientations and corresponding ΔE_{Z} values for a 1P-2P qubit pair and FIG. 14B shows possible nuclear spin orientations and corresponding ΔE_{Z} values for a 2P-3P qubit pair.

### DETAILED DESCRIPTION

The electron or nuclear spin of a donor atom in silicon represents a natural, highly coherent quantum bit. It is bound to a well-defined confining potential. The recent demonstrations of high-fidelity single-shot readout and control of both the electron and the nuclear spins of a ³¹P donor in a silicon nanostructure have added momentum to this quantum computer architecture. The next step is to perform quantum logic operations on these qubits.

In silicon quantum computing architectures, a qubit may be represented by an electron or nuclear spin of a single donor atom embedded in silicon crystal lattice. Such qubits are referred to as “single-donor qubits” in silicon. A qubit may also be represented by the electron spin associated with two or more closely spaced donor atoms embedded in the silicon crystal lattice, such a system is referred to as “multi-donor qubits” in silicon. For example, in the case of single-donor qubits in silicon, creating a quantum logic gate between two single-donor qubits for performing a quantum logic operation requires precise control of the electron-electron exchange interaction J between two adjacent donor atoms. Typically, the electron-electron exchange J takes place via the Heisenberg exchange interaction—which is a quantum mechanical effect that occurs between identical particles.

Although Heisenberg exchange interaction is an attractive way for qubits to interact (as it offers a compact route for quantum processors), achieving this interaction consistently and controllably across multiple silicon-based qubits is often problematic. Furthermore, wavefunction engineering options have been proposed, where the electron valley composition of silicon is modified either by coupling to an interface state or by using strained silicon. However, there are problems associated with the complex fabrication process that these techniques involve and the impact of interface traps, roughness, or strain inhomogeneity on exchange variations, electron coherence, and device reliability.

Accordingly, methods and systems for enabling effective quantum logic operations on qubits in donor-based silicon quantum processors is desired. Aspects of the present disclosure provide one or more such methods and systems.

Electron or nuclear spin qubits in donor-based silicon quantum systems are typically operated at magnetic fields of B₀˜1 T. The presence of the magnetic field leads to a Zeeman splitting of the energy levels of the electron/nuclear spin qubits (E_{Z}=gμ_{B}B₀). The difference in energy splitting between the two adjacent qubits, ΔE_{Z}, plays an important role when implementing a quantum logic operation (e.g., a two-qubit gate operation) on these two adjacent qubits. To date, the most explored method of coupling single-electron spin qubits is via exchange interaction (as discussed above), where the magnitude of J can be precisely controlled using voltage pulses applied to gates near the spin qubits. When exchange coupling is applied, the effective coupling strength between the anti-parallel electron spin states |↓↑ [symbol] and |↑↓ [symbol] depends not only on J but also on ΔE_{Z}, and can be expressed as Ω=\sqrt{J²+ΔE_{z}²}, where Ω is the effective coupling strength. Hence, the inventors of the present application have determined that magnitude of ΔE_{Z} is an important factor to consider when designing two-qubit exchange-based gate operations.

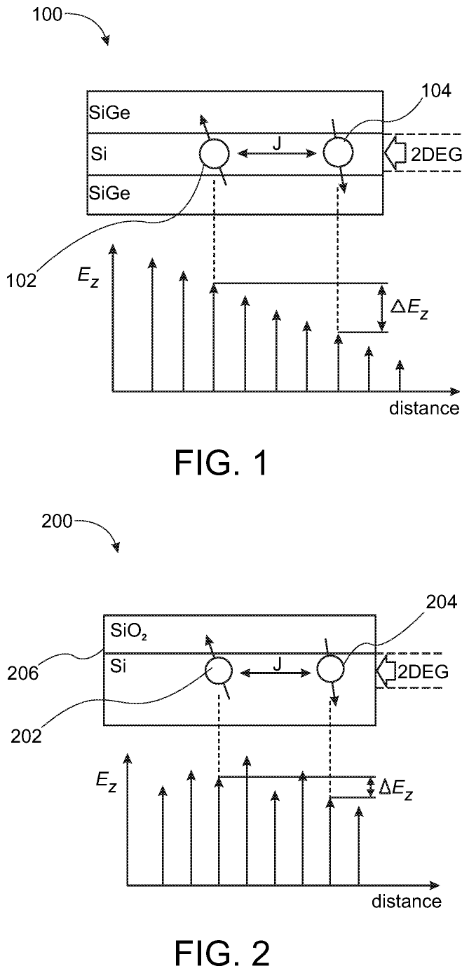

For gate-defined quantum dots, formed at the Si/SiGe and Si/SiO2 interfaces, the Zeeman splitting of each qubit is defined by the local magnetic field B₀ as well as the local electric field, which can affect the electron g-factor due to the Stark shift effect. FIG. 1 schematically shows a Si/SiGe device where the difference in qubit energies is achieved by placing qubits in a magnetic field gradient produced by a specially designed micromagnet. In particular, FIG. 1A shows a quantum processing device 100 with two electron spins 102 and 104 in two quantum dots electrostatically defined within a two-dimensional electron gas (2DEG) at an interface between Si and SiGe. A micromagnet (not shown) placed on the surface of the quantum processing device 100 close to the two electron spins 102, 104 generates a local magnetic field.

The bottom panel in FIG. 1 shows gradient in Zeeman energy E_{z} as a function of distance between the two electron spins 102 and 104. Further, ΔE_{Z} between qubits arises due to the local magnetic field produced by the micromagnet.

Silicon MOS (Si-MOS) devices that include gate defined quantum dots, on the other hand, typically utilise ΔE_{Z} naturally arising from the roughness of an interface between a silicon substrate and a barrier material such as silicon dioxide. This results in variations in the g-factor of electrons amongst different qubit sites. FIG. 2 illustrates an example of such a device 200. In particular, FIG. 2 depicts a Si-MOS device 200, in which 2DEG forms at the interface between silicon and the barrier material (e.g., SiO₂). The device 200 includes two electron spins 202 and 204 having an exchange coupling of J between the two electron spins 202, 204. In such a device, the electron spins experience spin-orbit mediated variations in their g-factor due to atomic non-uniformities at the Si/SiO2 interface 206. As a result, ΔE_{Z}, between neighbouring electron spins is of the order of ˜10 MHz.

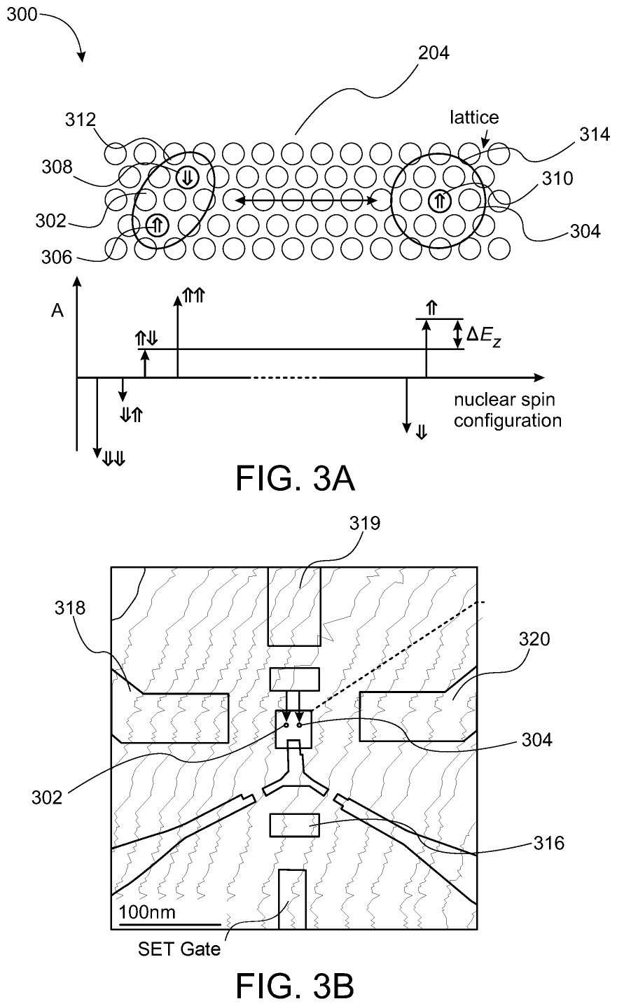

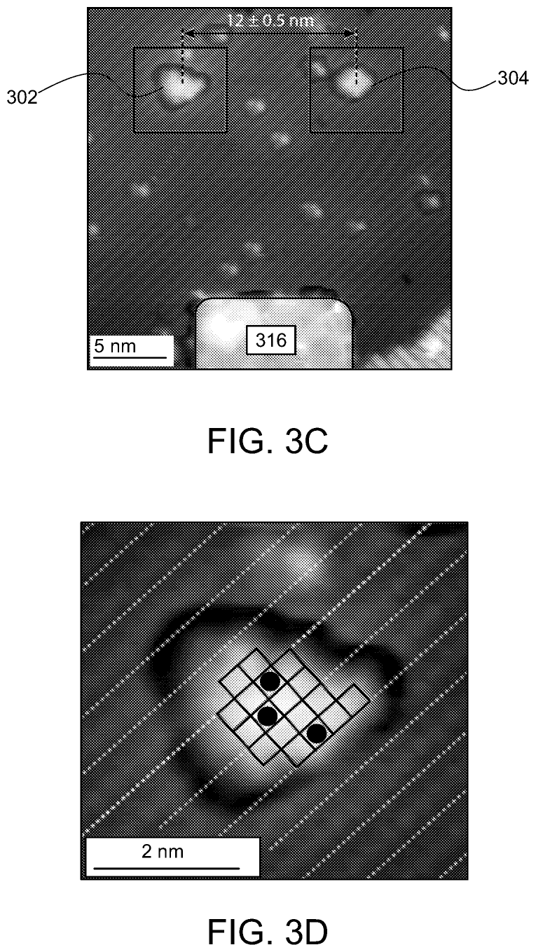

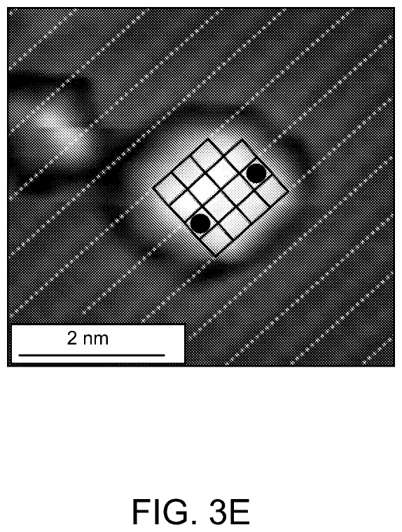

Inventors of the present disclosure determined that unlike gate-defined quantum dots, the energy splitting in donor or acceptor-based qubits depends on the hyperfine coupling between the electron or hole spin and the nuclear spin of the qubit-hosting donor or acceptor atom (or atoms). To illustrate this, FIG. 3 schematically illustrates two adjacent qubits within a multi-qubit quantum processing device 300. The device 300 includes at least dopant dots 302 and 304. Each dopant dot may include one or more acceptor or donor atoms. In case the dopant dot includes donor atoms, the atoms may be phosphorus atoms. In this present example, the left dopant dot 302 includes two P donor atoms 306, 308 and the right dopant dot 304 includes one P donor atom 310. Further, electron spin qubits 312, 314 can be confined by the P donors in the left and right dopant dots 302, 304, respectively. In particular, electrons can be spatially bound to the donor atoms in each dopant dot. In the example shown here, an electron may be confined by the pair of closely placed P donors in the left donor dot 302, and another electron may be confined by the single phosphorus donor atom in the right donor dot 304. The grey ovoids around the dopant atoms illustrate the electron confinement shape of each of the donor dots. The shape of the ovoids and the electron confinement is determined based on the number of P atoms in each donor dot. As the left dopant dot includes two donor atoms, it has an oval shape, whereas the right dopant dot includes one donor atom and is more spherical in shape.

When the dopant dots are formed of donor atoms (as shown in the example above), the dots are referred to as donor dots in this disclosure. Alternatively, when the dopant dots are formed of acceptor atoms, the dots may be referred to as acceptor dots. Further, when donor dots are used, electrons may be confined in the dots. Alternatively, when acceptor dots are used, holes may be confined in the dots. In the remainder of this disclosure, gate operations are described with respect to donor dots. However, it will be appreciated that these teachings equally apply to acceptor dots or acceptor based qubits.

For atom qubits, the energy difference between two qubits, ΔE_{Z}, is dominated by the hyperfine interaction, A, between electron (light blue ovoids) and nuclear spins (double-lined arrows) and the orientation of the nuclear spins. Further, the inventors of the present disclosure have identified that the hyperfine interaction A can be controlled by a number of parameters, in particular, the number of donor atoms in each of the quantum dots, arrangement of the donor atoms within the quantum dot and within the silicon crystal lattice, number of electrons in the quantum dot, and strain and electric fields (applied/background fields) in the device.

Controlling one or more of these parameters allows tuning of the hyperfine interaction A between the nuclear and electron spins within a donor-based qubit, thereby controllably creating energy difference ΔE_{Z} between two donor-based qubits. This control over the energy difference ΔE_{Z} allows an effective implementation of quantum logic gate operations on the qubits of the donor-based quantum processing device.

Some aspects of the present disclosure control the nuclear spins and in particular the orientation of the nuclear spins to, thereby controllably create energy difference ΔE_{Z} between two donor-based qubits affecting two-qubit gate operations.

In particular, some aspects of the present disclosure utilize multi-donor qubits to perform gate operations and optimize or dynamically control the ΔE_{Z} value to increase the fidelity of such gate operations. In one example, aspects of the present disclosure perform these gate operations on pairs of qubits that include at least one donor atom in one qubit and at least two donor atoms in the second qubit. More generally, if N represents the number of donor atoms in one qubit and M represents the number of donor atoms in a second qubit, the qubit pair may be selected such that N≥1 and M is >1.

For conditional two-qubit gates, i.e., gates where a second qubit (a target qubit) is subjected to a given operation conditional on the state of the first qubit (a control qubit), maximizing the energy difference ΔE_{Z} between the qubits increases the fidelity of the gates. The conditional two-qubit gates include CROT gates (i.e., gates where the target qubit is subjected to a rotation operation conditional on the state of the control qubit) and CPHASE gates (i.e., gates that induces a phase on the target qubit conditional on the state of the control qubit). Both CROT and CPHASE gates can be used to achieve one of the key gates in quantum computing—a CNOT gate. A CNOT gate flips a target qubit conditional on the state of a control qubit (i.e., the state of the target qubit is flipped only if the control qubit is in state |1 [symbol] ). In addition to the conditional gates, SWAP gates (i.e., gates that swap the state of the two qubits involved in the operation) and \sqrt{SWAP} gates (i.e., gates that perform half-way of a two-qubit swap) are also important to be implemented in quantum computing processors. For SWAP and \sqrt{SWAP} gates minimizing the energy difference ΔE_{Z} between the qubits is beneficial as this improves the performance and fidelity of these gates.

Therefore, the energy difference ΔE_{Z} between the qubits is selected based on the type of two-qubit gates required. Depending on the qubit gates required, optimal values of one or more of the parameters may be selected. For example, depending on the required qubit gate, one or more of optimal initial orientations of nuclear spins of the two qubits, optimal number of donor atoms in the qubits (e.g., N, M), optimal arrangement of the donor atoms of the qubits within the silicon crystal lattice, optimal number of electrons in the qubits, and so on may be selected. For example, the energy difference ΔE_{Z} between the qubits can be minimized for a SWAP gate by minimizing the hyperfine interaction A through shielding the nuclear spins with addition of multiple electrons in each qubit. In another example, this can be achieved by orienting the nuclear spins within both qubits such that the effective energy difference ΔE_{Z} is minimized.

Further still, according to aspects of the present disclosure, optimization of any of these two-qubit gate operations can be performed at two stages—during fabrication or during operation of the quantum processing system. In particular, according to aspects of the present disclosure, the fabrication of qubits can be optimized for a given two-qubit gate by precisely positioning donors within the silicon crystal lattice—this precise positioning can increase or decrease the ΔE_{Z} value. For example, if creating a two-qubit CNOT gate (that is derived from CROT or CPHASE gates), the multiple donor atoms can be precisely positioned in the crystal lattice for each donor such that the ΔE_{Z} value can be maximized. Alternatively or in addition, when operating the quantum processing system, aspects of the present disclosure can optimize for a given two-qubit gate by initializing nuclear spins in desired orientations such that the energy difference ΔE_{Z} between qubits is most optimal for a given two-qubit gate. For example, if a CNOT gate operation is required, the nuclear spins of the two qubits can be initialized such that the ΔE_{Z} value is maximized. Similarly, if a SWAP gate operation is required, the nuclear spins of the two qubits can be initialized such that the ΔE_{Z} value is minimum. With such dynamic control of ΔE_{Z} during operation, any qubit gate can be performed on multi-donor qubits.

These and other aspects of the present disclosure will be described in the following sections with respect to two types of gates—SWAP and CNOT gates. However, it will be appreciated that dynamically controlling the hyperfine interaction between the electron spin and the donor nuclear spin(s) or the orientation of the nuclear spins can be used to perform other logic operations without departing from the scope of the present disclosure.

Further, the aspects of the present disclosure will be described with respect to donor based quantum processing systems. One such quantum processing device 300 is displayed in FIG. 3A. FIG. 3B shows a schematic top view of the two-qubit device 300.

The device 300 may be fabricated on a p-type Si substrate. The substrate may be subjected to a series of high-temperature annealing processes up to ˜1,100° C. followed by a controlled cool-down to ˜330° C., at which point the surface is terminated with mono-atomic hydrogen via thermal cracking. The result is a fully terminated H:Si (2×1) reconstructed surface from which hydrogen can be selectively removed with an STM tip. Using the STM tip a lithographic mask representing the device and donor qubits is created on the Si surface. Subsequent adsorption and incorporation (at 350° C.) of gaseous PH₃ precursor metallizes the exposed area with ˜¼ monolayer of phosphorus. Then, a layer of Si is grown epitaxially to encapsulate the device. The typical thickness of encapsulation layer is between 20 nm and 100 nm.

The whole device 300 may be epitaxial—i.e., the donor dots 302, 304 may be fabricated within a substrate (such as a p-type Si substrate (1-10 Ωcm). Positioning the donor dots epitaxially can significantly reduce impact of noise on the qubits 312, 314. In some examples, the qubits 312, 314 are formed about 20-50 nm from the surface and separated by approximately 10-15 nm.

The qubits 312, 314 are tunnel coupled to a single-electron transistor SET 316 that acts as a charge sensor and electron reservoir to load the electrons onto the donor dots. Further, the qubits may be controlled by one or more gates. FIG. 3B illustrates three gates—left gate 318, middle gate 319, and right gate 320, which can be used to control the electrochemical potentials of the donor dots, whereas the SET gate is predominately used to control the electrochemical potential of the SET 316. In one implementation, the gates 316-320 may be metal contacts on the surface. In another implementation, the gates may be phosphorus-doped silicon (SiP) gates fabricated epitaxially within the semiconductor substrate. In either case, the gates 318-320 allow full electrostatic control of the qubits 312, 314.

Although an SET is depicted in FIG. 3B, qubit readout can be performed using other mechanisms. For instance, it may be performed dispersively using the gates 318-320.

To perform initialization or gate operations, the nuclear spins of the dopant dots need to be controlled. In the most basic implementation, a global or local nuclear magnetic resonance (NMR) antenna may be used to control the nuclear spins via radio frequency (RF) magnetic fields in the range of about one hundred MHz. The NMR antenna (not shown) can be manufactured on chip, or off chip (e.g., as a cavity or coil).

Electronic structures for readout and control can be placed on chip, or on the printed circuit board (PCB) which holds the silicon chip. They include waveguides, resonators, bias tees, amplifiers, filters, mixers circulators, etc. Any of these structures can be implemented using on chip lithographic structures or on the PCB using commercially available surface mount devices (SMD).

FIGS. 3C-E show STM schematic images of the donor dots 302, 304 in device 300 taken after hydrogen lithography. However, in this example, the donor dots include 3P and 2P atoms, instead of 2P and 1P atoms as shown in FIG. 3A. In particular, FIG. 3C shows the top part of the SET transistor and the two donor dots 302, 304. The left dot includes 3P atoms and the right dot includes 2P atoms. FIG. 3D shows a close-up of a lithographic patch of the left donor dot 302. FIG. 3E shows a close-up of a lithographic patch of the right donor dot 304. The diagonal dashed lines in FIGS. 3D and 3E represent the dimer rows on the hydrogen-terminated (100) silicon surface. The black squares in these figures represent the sites on the surface of the silicon lattice, for which the hydrogen mask was removed. The black dots indicate possible/estimated positions of donor atoms P in the silicon lattice.

The fabrication of the multi-donor qubits shown in FIGS. 3A-3E relies on patterning lithographic patches of a specific size within the hydrogen mask. If the size of the lithographic patch is exactly 3 dimers along a dimer row (i.e., 6 black squares in FIG. 3D or 3E), then most likely no more than 1 donor will be incorporated. The exact dependence between the patch size and donor number is to some extent probabilistic in nature due to the different chemical pathways that can take place. However, generally, the larger the lithographic patch the more donors can be incorporated. In the example shown in FIGS. 3C-E, 18 hydrogen atoms (black squares) were desorbed in the left patch and 15 hydrogen atoms were desorbed in the right patch, which resulted in 3 and 2 donors in the left and right donor dots 302, 304, respectively. To create donor dots with other numbers of donor atoms, different sized patches may be desorbed. For instance, to create the donor dots shown in FIG. 3A, 15 hydrogen atoms may be desorbed from the left donor dot 302 (to incorporate 2 P atoms) and 6 hydrogen atoms are desorbed from the right donor dot 304 (to incorporate 1 P atom). The number of donors incorporated within a given lithographic patch can be regulated not only by controlling the size of the lithographic patch, but also with other methods such as tip-assisted incorporation, control of the phosphine dosing parameters, and/or control of the incorporation parameters.

In this way, to achieve a desired hyperfine interaction and hence a desired qubit energy difference ΔE_{Z}, an optimal number of donor atoms in each qubit can be incorporated during the fabrication stage.

### Impact of Electric Field on Transition Energies of Qubits Hosted on Multi-Donor Dots

In a further embodiment of the present disclosure, an electric field is applied to at least one of the donor dots that comprises two or more donor atoms. The electric field is applied at a predetermined angle to a central axis of the donor dot.

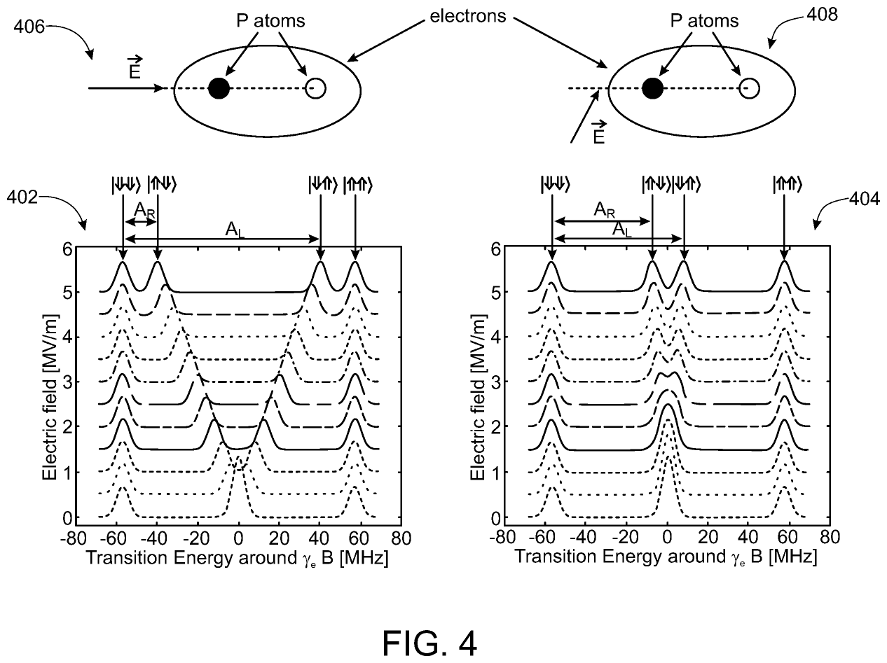

The strength of the hyperfine coupling for multi-donor dots is predominantly dependent on the number of donors and their mutual atomic configuration. However, the hyperfine coupling can be altered via Stark shift effect when electric fields are present in the device. This means that the electric field can push the electron wavefunction towards or away from the donor, thus altering the strength of hyperfine coupling. The impact of the Stark shift effect on the qubit transition energies is schematically shown in FIG. 4, where the ESR spectra for a 2P qubit are presented as a function of electric field in two charts 402, 404. The chart 402 corresponds to a situation where electric field is applied parallel to the 2P axis (see schematic 406), where the 2P axis is defined as a line connecting the two donor atoms within the silicon crystal lattice. The chart 404 corresponds to a situation where electric field is applied at a certain angle with respect to the 2P axis (see schematic 408). In absence of electric fields, the electron wavefunction is typically positioned symmetrically between the two donor atoms such that the hyperfine coupling for both donor atoms is similar. Therefore, in the absence of electric field the ESR spectra of a 2P qubit show three peaks corresponding to [symbol] , [symbol] / [symbol] , and [symbol] nuclear spin orientations as seen in the bottommost plots in charts 402, 404. As the electric field is increased, the individual hyperfine couplings can change and consequently the middle peak can be split into two peaks, [symbol] and [symbol] . In case the electric field is applied parallel to the 2P axis, (plot 402), the Stark shift effect is relatively strong as the electron wavefunction can be pushed from one donor site to another. In case the electric field is applied at an angle to the 2P axis, the Stark shift effect is weaker as only a component of electric field can shift the position of electron wavefunction between the donor sites.

### CNOT Gates

This section describes the theoretical framework for performing CNOT gates via controlled rotation (CROT) using multi-donor dots. Although this section describes the CNOT operation via controlled rotations, the teachings of the present disclosure can just as easily be applied to performing CNOT gates via controlled phase gates (CPHASE). Further, this section shows that multi-donor dots can be used to achieve high-fidelity CNOT gates, by utilizing their nuclear spins as nano-magnets. In particular, it is shown that the nuclear spins of multi-donor dots can be initialized to create a large energy difference between two dots, several times larger than in case of single-donor dots. As a result, multi-donor dots can be used to perform CNOT gates. In this example, it is shown that a CNOT gate is achieved with reduced leakage and up to 4 times lower CNOT gate error as compared to single donors. Additionally, it is shown that the CNOT gate can be further optimised by atomic precision placement of donors within multi-donor dots. This precision in atomic placement is shown to further improve the fidelity of the CNOT gate.

A CPHASE gate relies on a voltage pulse that introduces a phase to the |↓↑ [symbol] and |↑↓ [symbol] states. When combined with single-qubit operations, a CPHASE gate can be used to execute a two-qubit CNOT gate. A CROT gate, on the other hand, is a resonantly driven gate that relies on a control qubit governing the energy of a target qubit. Both CPHASE and CROT gates are operated in the regime where the exchange coupling J is much smaller than the Zeeman energy difference, ΔE_{Z}, between the qubits. In this regime, J is relatively insensitive to charge noise, making both CROT and CPHASE promising candidates for achieving high fidelity gates. The CROT gate is particularly attractive due to its simplicity, since the CNOT gate can be directly implemented in a single step via an adequately timed CROT operation.

In aspects of this disclosure, a CROT gate is disclosed between electron spins hosted on multi-donor dots 302, 304 where each donor nuclear spin can be used as an atomic ‘magnet’. In particular, aspects of the present disclosure dynamically optimize the qubit energy difference, ΔE_{Z}, by preparing the donor nuclear spins in the most suitable orientation.

In the case of the CROT gate, a large ΔE_{Z} is desirable since the gate is operated in the J<<ΔE_{Z} regime. For two-qubit gates between exchange-coupled pairs of single P atoms, the ΔE_{Z} parameter is limited by the hyperfine coupling of a single donor to 117 MHz. Assuming experimentally feasible control parameters, it is calculated that CNOT gate fidelities exceeding 99.9% are achievable between electrons hosted on single donors in isotopically purified ²⁸Si. It is found that multi-donor qubits are particularly well-suited for the CROT operation since they can produce notably large energy differences ΔE_{Z}, in excess of 700 MHz, due to the presence of multiple donor atoms providing a larger total hyperfine interaction.

Consequently, errors associated with tilted rotation axis in the two-qubit subspace are minimised. In order to determine the level of impact that ΔE_{Z} has on the CNOT fidelity, a numerical model is constructed that includes the interplay between different CNOT gate error sources, including charge noise. The model enables determination of the optimal experimental parameters, such as the drive frequency and the gate duration time, that maximise the CNOT gate fidelity. In particular, it is determined that the CNOT fidelities depend on the number of P donors in each qubit as well as the atomic configuration of the P atoms within each qubit. Importantly, it was determined that atomically-engineered multi-donor qubits are capable of CNOT fidelities as high as 99.97% assuming realistic level of charge noise (˜σ_{ε}=1 μeV).

### Operation of the CROT Gate

A two-qubit CROT gate requires both electric and magnetic control. The magnetic control, needed to drive the individual electron spins, can be achieved using electron spin resonance (ESR) techniques. The electric control, necessary to control the J coupling, can be implemented by applying voltages to electrostatic gates 318-320 to detune the relative energy of the two qubits. Due to the J coupling, the ESR transition of each qubit becomes dependent on the state of the other qubit, which is the basis of the CROT gate.

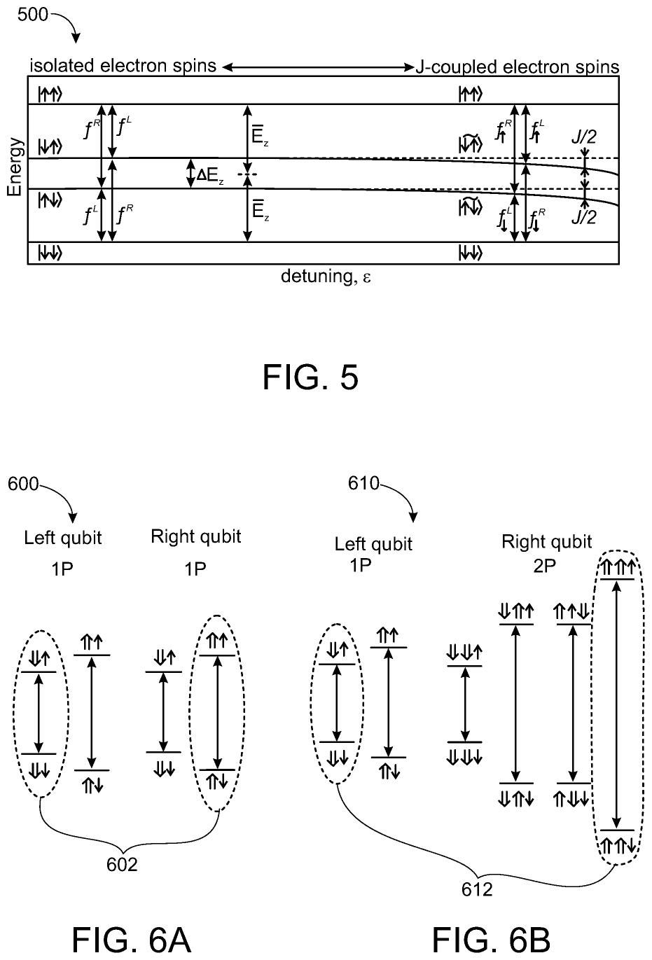

To illustrate this, FIG. 5 shows a schematic energy diagram 500 of a two-electron-spin system as a function of detuning energy, where Ē_{Z} is the average Zeeman splitting of the qubit pair and ΔE_{Z} is the energy difference between qubits.

The left-hand side of the energy diagram 500 corresponds to the isolated spin basis {|↓↓ [symbol] , |↓↑ [symbol] , |↑↓ [symbol] , |↑↑ [symbol] }, where the arrows correspond to the ESR transitions of the left and right qubit, as notated. As the detuning ε, is increased, the exchange coupling J changes the transition energy f^{L}, f^{R} of the left and right qubit by J/2, and this change can be positive or negative depending on the spin orientation of the right or left qubit, respectively. As seen from this figure, at large negative detunings (i.e., the left-hand side of the energy diagram 500), the electrons are well separated, and the exchange interaction, J is small. As the detuning is increased (i.e., moving toward the right-hand side of the energy diagram 500), J detunes the qubits transition energies, depending on the spin of the second electron. The right-hand side of the energy diagram 500 corresponds to the hybridised basis of the spin states {|↓↓ [symbol] , [symbol] , [symbol] , |↑↑ [symbol] }, where the tilde indicates the hybridisation of the anti-parallel states, {|↓↑ [symbol] , |↑↓ [symbol] }, due to finite exchange energy J.

During CROT operation, a timed ESR pulse rotates a target qubit, under the condition that a control qubit is in a |↑ [symbol] state. Throughout this disclosure, the left qubit 312 is arbitrarily selected as the target qubit whereas the right qubit 314 is selected as the control qubit, so that the ESR pulse applied at frequency

$${f}_{\vert ↑ 〉}^{L} = {f}^{L} + \frac{J}{2}$$

rotates the left or target qubit only if the right (or control) qubit is in the |↑ [symbol] state. The CNOT gate is achieved when the controlled rotation angle is exactly π.

Importantly, the CROT gate requires that J is much smaller than the local magnetic field difference between the two qubits, ΔE_{Z}, so that the two-electron-spin system remains in the computational eigenbasis. If this requirement is not met, the two-electron-spin states deviate from the computation basis and ‘leak’ into the singlet-triplet basis, which translates into CROT gate error as detailed in the following paragraphs. Therefore, to achieve a high-fidelity CROT gate, it is desirable to engineer a large ΔE_{Z}.

### Using Multi-Donor Qubits to Optimise the Rotation Angle During CROT Operation

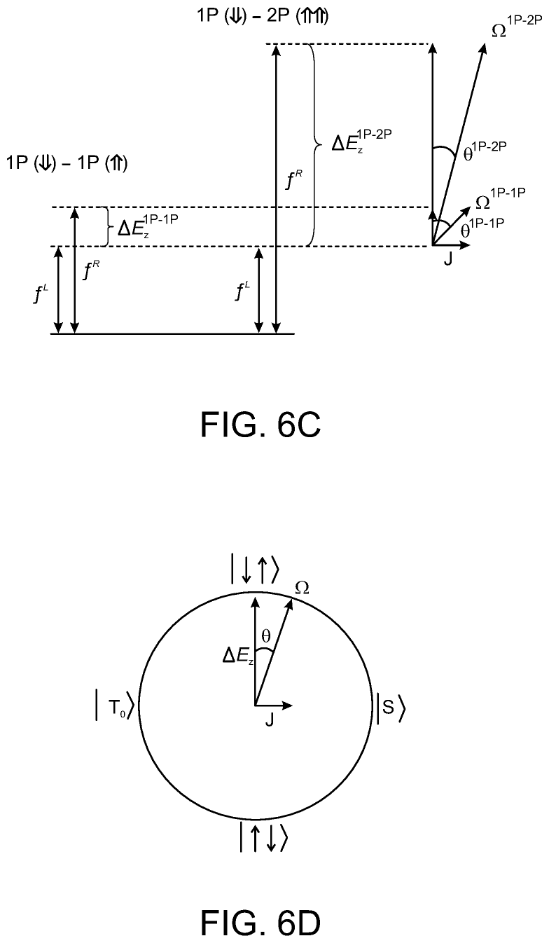

To illustrate the benefit of multi-donor qubits, in FIGS. 6A and 6B, the energy level diagrams 600 and 610 between a 1P-1P qubit pair and 1P-2P qubit pairs, respectively, is compared along with their ESR transitions marked by vertical double-headed arrows. Single (↓/↑) and double ( [symbol] ) arrows in these diagrams represent electron and nuclear spin states, respectively. For each qubit pair, indicated within the dashed ovoids are the anti-parallel nuclear spin configurations that provide the largest possible difference in transition energies between the two qubits.

Each ESR transition corresponds to a specific configuration of the nuclear spin states, with two possible configurations for a 1P qubit, [symbol] and [symbol] and four configurations for a 2P qubit, [symbol] , [symbol] , [symbol] , [symbol] . Prior to executing a CNOT gate, the nuclear spins of the P donors within the dots are initialised so that the qubit transition energies are known and fixed throughout the CNOT gate operation. The desired orientation of nuclear spins can be achieved via nuclear magnetic resonance (NMR) techniques using AC magnetic pulses.

For the CNOT gate, it is beneficial to orientate the donor nuclear spins so that the nuclear spins in one donor dot are anti-parallel to the nuclear spins in the other donor dot, that is [symbol] for 1P-1P and [symbol] for a 1P-2P system, for example all P nuclear spins in the left qubit pointing down and all P nuclear spins in the right qubit pointing up. Examples of such anti-parallel nuclear spin configurations are highlighted with the dashed lines 602 and 612 in FIGS. 6A and 6B, respectively.

Next, in FIG. 6C, the ΔE_{z} values that arise from these anti-parallel nuclear spin configurations for 1P-1P and 1P-2P qubit pairs are compared. As seen from the figure, the qubit energy difference, ΔE_{z}, is much larger for the 1P-2P configuration than for 1P-1P configuration due to strong electron confinement, and hence larger hyperfine coupling, A, of the 2P qubit. As a result, the angle θ=arctan (J/ΔE_{Z}) for exchange-coupled 1P-2P qubits is smaller than in case of 1P-1P qubits.

Large values of ΔE_{z} are desirable for a two-qubit CROT gate as they minimise errors (i.e. improve fidelity) associated with quantum state leakage out of the computational subspace. The advantage of a large ΔE_{z} value is also schematically shown in FIG. 6D. In particular, FIG. 6D depicts a schematic representation of a Bloch sphere of a two-electron spin system. Since the qubits are measured in the single spin basis, any deviation from the vertical ↓↑/↑↓ axis results in state leakage into the singlet-triplet (S-T₀) basis. Since the 1P-2P qubit pair provides a smaller angle θ, the leakage error during the CNOT gate is reduced in a multi-donor qubit example.

During the controlled rotation of the target qubit, the two-electron-spin system is in hybridised basis {|↓↓ [symbol] , [symbol] , [symbol] , |↑↑ [symbol] }, where the effective coupling between the [symbol] and [symbol] corresponds to—

$$Ω = \sqrt{Δ {E}_{z}^{2} + {J}^{2}} \qquad ( 1 )$$

The hybridisation of the anti-parallel states can be quantified using the angle θ=arctan (J/ΔE_{Z}) that defines the two-qubit basis as follows:

$$\vert 〉 = - sin ( \frac{θ}{2} ) \vert ↓ ↑ 〉 + cos ( \frac{θ}{2} ) \vert ↑ ↓ 〉 , \qquad ( 2 )$$

$$\vert 〉 = cos ( \frac{θ}{2} ) \vert ↓ ↑ 〉 + sin ( \frac{θ}{2} ) \vert ↑ ↓ 〉 , \qquad ( 3 )$$

$$Where$$

$$sin ( \frac{θ}{2} ) = \frac{J}{\sqrt{( Δ {E}_{{z}^{+}} {\sqrt{Δ {E}_{Z}^{2} + {J}^{2} )}}^{2} + {J}^{2}}} \qquad ( 4 )$$

$$cos ( \frac{θ}{2} ) = \frac{Δ {E}_{{z}^{+}} \sqrt{Δ {E}_{z}^{2} + {J}^{2}}}{\sqrt{( Δ {E}_{{z}^{+}} {\sqrt{Δ {E}_{z}^{2} + {J}^{2} )}}^{2} + {J}^{2}}} \qquad ( 5 )$$

After the controlled rotation, both qubits are independently measured via a projective spin readout, which requires no J interaction between the qubits during the measurement. The readout is therefore performed in the eigenbasis of isolated electron spins {|↓↓ [symbol] , |↓↑ [symbol] , |↑↑ [symbol] }. Because of the projective readout, the θ angle determines the unwanted leakage from the computational eigenbasis into the singlet-triplet (S-T₀) basis, as schematically presented on the Bloch sphere in FIG. 6D. Consequently, both qubits leave their two-level {|↓ [symbol] , |↑ [symbol] } qubit subspace, which manifests itself as an error in the CNOT gate. When projected onto the measurement axis, the visibility of the target qubit Rabi oscillations is reduced and can be written as

$${V}_{Rabi} = \frac{Δ {E}_{z}}{\sqrt{Δ {E}_{z}^{2} + {J}^{2}}} \qquad ( 6 )$$

Therefore, a large ΔE_{z}/J ratio is required to achieve high-fidelity two-qubit CROT gate. As shown in FIG. 6C, the 1P-2P qubit pair provides a larger ΔE_{z} and smaller θ as compared to single donors (1P-1P). To quantify the impact of donor numbers on the two-qubit gate fidelity, in the following sections a theoretical model is used to calculate the CROT gate fidelities for multi-donor qubits.

### Model

To quantify the impact of ΔE_{z} on the CNOT gate fidelity, a numerical model is constructed based on the time-evolution of the two-electron-spin Hamiltonian:

$$H = {\overbrace{{\sum }_{i = 1}^{2} {γ}_{e} {B}_{0} {S}_{{z}_{i}}}}^{{H}_{z}} + {\overbrace{{\sum }_{j = 1}^{{N}_{L}} {A}_{j}^{L} {S}_{1} \cdot {I}_{j}^{L} {\sum }_{k = 1}^{{N}_{R}} {A}_{k}^{R} {S}_{2} \cdot {I}_{k}^{R}}}^{{H}_{A}} + {\overbrace{J ( {S}_{1} \cdot {S}_{2} )}}^{{H}_{z}} . \qquad ( 7 )$$

Where γₑ is electron gyromagnetic ratio, B₀ is the global DC magnetic field strength, S and I are electron and nuclear spin operators, N_{L} (N_{R}) is a number of donors within the left (right) qubit, Aᵢ is the hyperfine strength between an electron and an individual donor site i, and the H_{Z}, H_{A} and H_{J} parts of the Hamiltonian correspond to the Zeeman, hyperfine and exchange contributions, respectively. The nuclear Zeeman energy of donor dots has been neglected as it is much smaller (˜20 MHz) than both the electron Zeeman energy (˜40 GHz) and the hyperfine energy (typically hundreds of MHz).

To drive the ESR transitions of donor qubits, an oscillating magnetic field B_{ac}(t) perpendicular to B₀ is used. In the rotating frame of the electron spin, the ESR drive can be considered constant B_{ac}(t)≈2B₁. Using this rotating frame approximation, in the absence of exchange interaction J the total two-electron Hamiltonian can be diagonalized and written in the {|↓↓ [symbol] , |↓↑ [symbol] , |↑↓ [symbol] , |↑↑ [symbol] } eigenbasis as—

$${H}_{RF} = \frac{1}{2} ( \begin{matrix}2 {E}_{Z} & {γ}_{e} {B}_{1} & {γ}_{e} {B}_{1} & 0 \\ {γ}_{e} {B}_{1} & - Δ {E}_{Z} & 0 & {γ}_{e} {B}_{1} \\ {γ}_{e} {B}_{1} & 0 & Δ {E}_{Z} & {γ}_{e} {B}_{1} \\ 0 & {γ}_{e} {B}_{1} & {γ}_{e} {B}_{1} & - 2 {\overline{E}}_{Z}\end{matrix} ) \qquad ( 8 )$$

where the energy difference, ΔE_{z}, between qubits L and R can be written as

$${Δ {E}_{z} = \vert {E}_{Z}^{L} - {E}_{Z}^{R} \vert \approx \vert {\sum }_{i = 1}^{{N}_{L}} ( {I}_{z} 〉}_{i} {A}_{i}^{L} - {\sum }_{j = 1}^{{N}_{R}} {〈 {I}_{z} 〉}_{j} {A}_{j}^{R} \vert \qquad ( 9 )$$

And the mean qubit energy, E_{z}, as—

$${{E}_{Z} = \frac{{E}_{Z}^{L} + {E}_{Z}^{R}}{2} \approx {γ}_{e} {B}_{0} + \frac{1}{2} ( {\sum }_{i = 1}^{{N}_{L}} ( {I}_{z} 〉}_{i} {A}_{i}^{L} + {\sum }_{j = 1}^{{N}_{R}} {〈 {I}_{z} 〉}_{j} {A}_{j}^{R} ) \qquad ( 10 )$$

where

$${〈 {I}_{z} 〉}_{k} = \pm \frac{1}{2}$$

is the expectation value of the nuclear spin operator of the k-th donor. In the presence of a finite J coupling between the qubits, the eigenbasis is changed to {|↓↓ [symbol] , | [symbol] , | [symbol] , |↑↑ [symbol] } and the corresponding Hamiltonian can be written as—

$${H}_{RF}^{J} = \frac{1}{2} ( \begin{matrix}2 {\overline{E}}_{Z} & {γ}_{S} {B}_{1} & {γ}_{T} {B}_{1} & 0 \\ {γ}_{S} {B}_{1} & - Ω - J & 0 & {γ}_{S} {B}_{1} \\ {γ}_{T} {B}_{1} & 0 & Ω - J & {γ}_{T} {B}_{1} \\ 0 & {γ}_{S} {B}_{1} & {γ}_{T} {B}_{1} & - 2 {\overline{E}}_{Z}\end{matrix} ) , \qquad ( 11 )$$

where γ_{S} and γ_{T} are the effective gyromagnetic ratios associated with singlet and triplet states, and can be expressed as:

$${γ}_{s} = {γ}_{e} [ cos \frac{θ}{2} - sin \frac{θ}{2} ] \qquad ( 12 )$$

$${γ}_{T} = {γ}_{e} [ cos \frac{θ}{2} + sin \frac{θ}{2} ] \qquad ( 13 )$$

Calculation of CNOT Gate Fidelity Using 1p-1p and 1p-2p Qubits

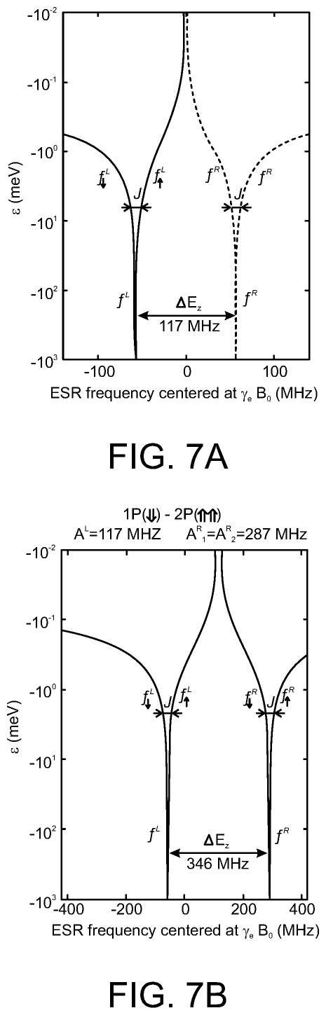

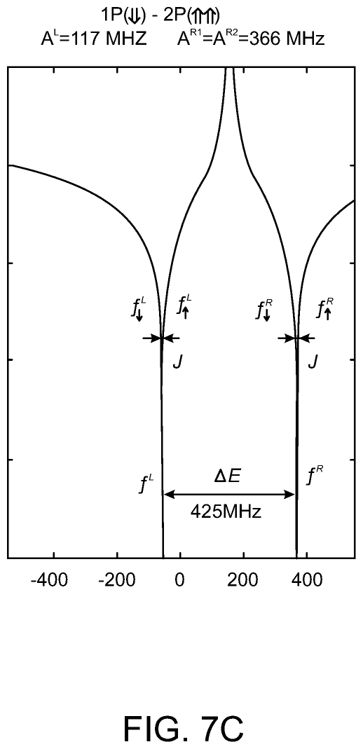

Using the theoretical framework outlined in the previous section, the CNOT fidelities achievable with 1P-1P and 1P-2P qubit pairs can be calculated. In particular, ESR transition energies can be calculated as a function of detuning for the 1P-1P qubit pair in FIG. 7A and for the 1P-2P pair in FIGS. 7B and 7C. In particular, FIG. 7A depicts the ESR spectra of a 1P-1P qubit pair with the left qubit nuclear spin initialised in a [symbol] state and the right qubit in a [symbol] state. Such antiparallel configuration yields an energy difference of ΔE_{Z}=117 MHz. As seen in these figures, the exchange coupling J splits the spectral ESR line of each qubit into two branches, separated in energy by exchange coupling J. FIGS. 7B and 7C depict the same ESR spectra for a 1P-2P qubit pair with nuclear states initialized in an anti-parallel [symbol] configuration that yields ΔE_{Z}=346 MHz in FIG. 7B and a ΔE_{Z}=425 MHz.

For the calculation of ΔE_{Z} values, equation 9 is used and the hyperfine value is assumed to be 117 MHz for the 1P qubit, which corresponds to the average bulk value of a single P donor in silicon, and 287 MHz for the 2P qubit system of FIG. 7B, which corresponds to 0.543 nm separation between the 2P atoms. Hyperfine value is assumed to be 366 MHz for the 2P qubit system of FIG. 7C, which corresponds to 0.384 nm separation between the 2P atoms. For all three qubit pairs, the exchange energy J (ε, t_{c}) is calculated using the Hubbard model as follows—

$$J ( ϵ , {t}_{c} ) = \frac{ϵ}{2} + \sqrt{\frac{{ε}^{2}}{4} + {r}_{c}^{2}} \qquad ( 14 )$$

with a tunnel coupling of t_{c}=4 GHZ, allowing for the exchange interaction J to be controllably switched on and off using one or more of the electrostatic gates 318-320 above the qubits. It has been experimentally shown that the tunnel coupling of t_{c}=4 GHz corresponds to the two qubits being separated by a distance of approximately 13 nm. As the detuning, ε, is increased, the ESR spectral line of the left (right) qubit is split into two lines that correspond to |↓ [symbol] and |↑ [symbol] spin states of the right (left) qubit, which can be written as—

$${f}_{↑}^{R} = {\overline{E}}_{Z} + \frac{1}{2} ( \sqrt{Δ {E}_{Z}^{2} + {J}^{2}} + J )$$

$${f}_{↓}^{R} = {\overline{E}}_{Z} + \frac{1}{2} ( \sqrt{Δ {E}_{Z}^{2} + {J}^{2}} - J )$$

$${f}_{↑}^{L} = {\overline{E}}_{Z} + \frac{1}{2} ( - \sqrt{Δ {E}_{Z}^{2} + {J}^{2}} + J )$$

$${f}_{↓}^{L} = {\overline{E}}_{Z} + \frac{1}{2} ( - \sqrt{Δ {E}_{Z}^{2} + {J}^{2}} - J )$$

Having determined the ESR spectra of exchange-coupled 1P-1P and 1P-2P qubit pairs, the corresponding CNOT gate fidelities are computed. This can be done by calculating the unitary of the time evolution of a two spin system Hamiltonian H^{J}RF (Eq. 11). The unitary operator is then used to calculate the process tomography matrix χ, which allows the process fidelity to be calculated as F=Tr (χ^{T} χ_{ideal}), where χ_{ideal} is the ideal CNOT process matrix. The ideal CNOT process matrix includes phase accumulations for each state, which can be corrected for using single-qubit rotations and a refocusing pulse sequence. To account for decoherence during the CNOT gate, Gaussian distributions with standard deviation σ_{ε} and σ_{mag} that correspond to charge noise and magnetic noise, respectively are considered. The CNOT fidelity is then calculated by sampling 15 values from each distribution and averaging over the corresponding time evolutions. In the simulations, charge noise of σ_{ε}=1 μeV, as reported for state-of-art silicon qubits, and a magnetic noise of σ_{mag}=2 kHz corresponding to isotopically purified silicon ²⁸Si with a residual ²⁹Si concentration of 800 ppm is considered. For the microwave ESR pulses, a square-shaped envelope of the oscillating ESR magnetic field is considered, which allows for faster Rabis as compared to other pulse shapes (e.g., Gaussian) with the same power. It is also assumed that the desired anti-parallel orientation of the nuclear spins is preserved throughout the experiment.

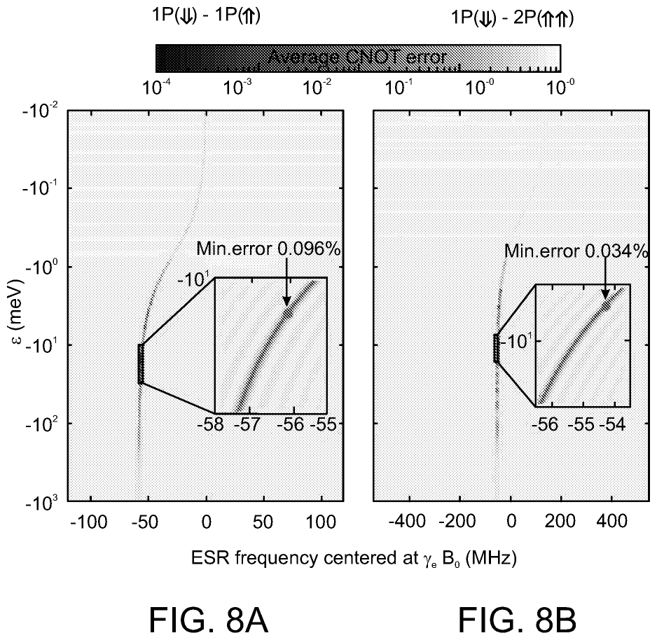

FIGS. 8A-8D show the calculated CNOT gate errors as a function of applied ESR frequency and detuning for 1P-1P qubit pair (FIG. 8A) and 1P-2P qubit pair (FIG. 8B). The gate time T_{CNOT} has been set to 2 μs, which results in the highest fidelity. For the 1P-1P system, the lowest error of 0.096% is found for f_{↑}^{L}=γₑB₀−56.1 MHz and ϵ=−13.3 meV. Similarly, for the 1P-2P system the optimal operating point was found for f_{↑}^{L}=γₑ B₀−54.3 MHz and ϵ=−7.8 meV with only 0.034% error.

The results show that the average CNOT error is three times smaller, as compared to single donors, when using 1P-2P donor dots to host the electron spins. This dramatic improvement can be attributed to the strong confining potential of the 2P donor dot that allows for increased magnitude of ΔE_{Z} and decreased state leakage.

CNOT Gate with Multiple Donor Numbers

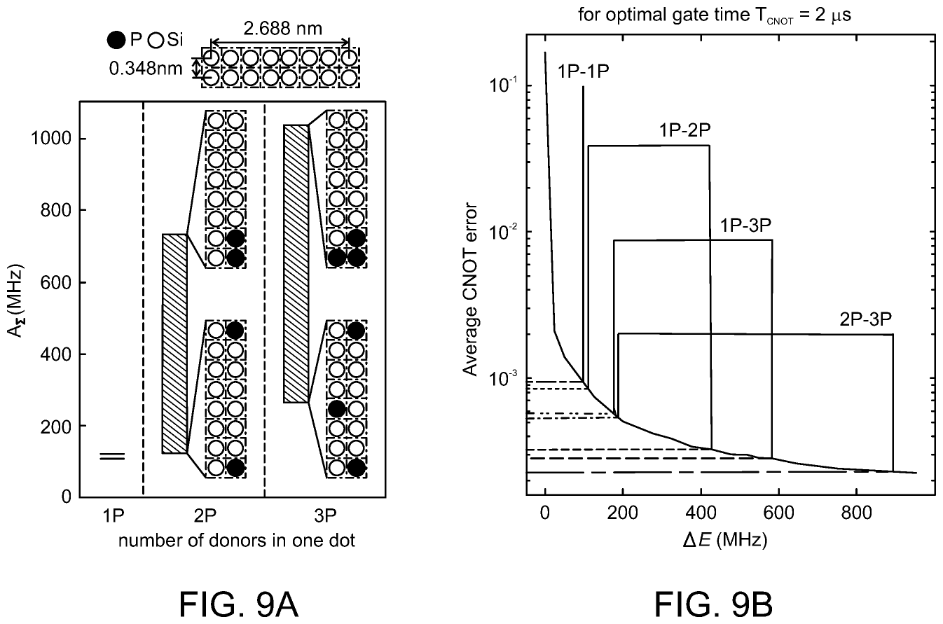

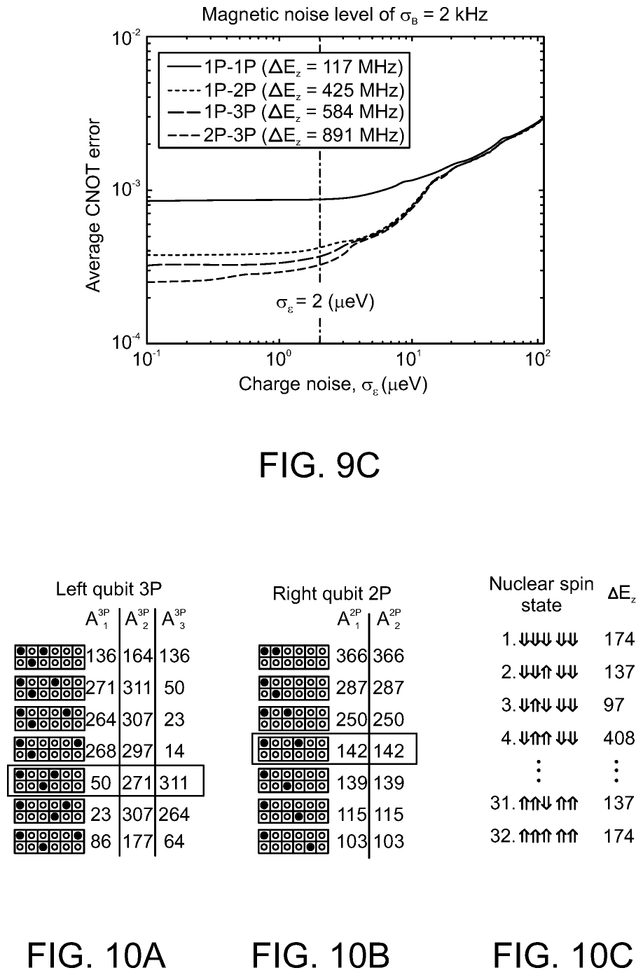

Having shown a 3-fold decrease in gate infidelity between 1P-1P and 1P-2P systems, we now look at the fidelity increase for donor dots that contain even more P atoms. The CROT gate can be, in principle, executed between electron spins hosted by any arbitrary number of donors in the qubits. However, the process of initialising all of the individual nuclear spins may become increasingly challenging for excessive numbers of P atoms within qubits. Therefore, fidelity calculations were performed on qubit pairs containing no more than four donors in total (such as 1P-3P and 2P-2P pairs). To begin, the span of possible hyperfine values for 1P, 2P and 3P qubits are considered, as shown in FIG. 9A. The insets in FIG. 9A show the orientation or position of P atoms in the silicon crystal that correspond to the lowest and highest hyperfine values when the dot includes one donor atom, two donor atoms, and three donor atoms. In cases of two and three donor atoms, the donors within a dopant dot are separated by less than 3 nm. For each electron spin qubit hosted by N Phosphorus atoms, the total hyperfine is computed as follows—

$${A}_{\sum } = {\sum }_{i = 1}^{N} {A}_{i} \qquad ( 15 )$$

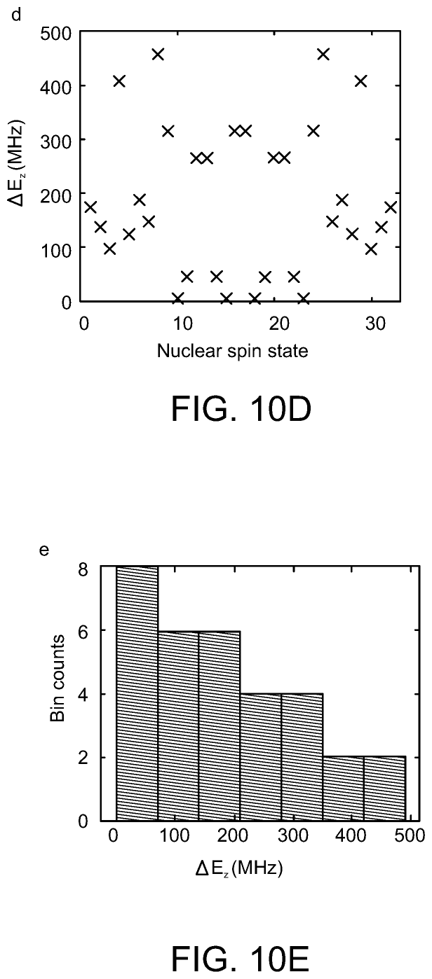

The hyperfine value of 1P is nominally fixed at 117 MHz. However, this value can be slightly reduced in the presence of electric fields due to the Stark shift effect. Unlike 1P, the 2P and 3P qubits do not have a fixed hyperfine value. Instead, A has been shown to depend on the exact crystallographic configurations of P atoms defining each qubit. When the donors within the dot are close together, they form a strong confining potential, as the electron is more tightly bound, which results in higher A. Similarly, low A values correspond to larger inter-donor separations within the dot, where the electron wavefunction is, on average, further away from each P atom. Consequently, depending on the crystallographic alignment of P atoms, the total hyperfine A_{Σ} can take values between 120 MHz and 732 MHz for the 2P qubit, and a range of 258-1050 MHz for the 3P qubit. The hyperfine values are obtained from tight binding numerical calculations, which consider qubit donor arrangements up to eight lattice sites in the [110] crystallographic direction and two sites in the [11̅0] direction. FIGS. 10A and 10B shows several examples of donor configuration for the 3P and 2P qubits, respectively.

Next, the CNOT fidelities that can be achieved with different qubit pairs, 1P-1P, 1P-2P, 1P-3P and 2P-3P are computed. It was noted that the error decreases for larger ΔE_{Z}, mainly due to reduced quantum state leakage.

The errors are calculated at the optimal detuning and ESR frequency, which means that for each point a plot like that shown in FIGS. 8A and 8B is plotted and the minimum error value is determined. An optimal CNOT gate time is determined at ˜2 μs, with the errors increasing for both faster and slower gate times. Fast CNOT gates (short T_{CNOT} time) correspond to broad excitation profiles in the frequency domain, which can lead to the unwanted driving of the transitions f_{↓}^{L} and f_{↓}^{R}, reducing the overall gate fidelity. On the other hand, slow CNOT gates suffer from the Overhauser dephasing as the resonant frequency of the target qubit fluctuates with the ²⁹Si nuclear bath. The competition between these two mechanisms sets an optimal gate time around T_{CNOT}˜2 μs (for 800 ppm ²⁹Si), regardless of the qubit donor numbers. Based on the previously determined A_{Σ} values for individual qubits, Eq. 9 can be used to find the ΔE_{Z} values obtainable with different qubit pairs: ≲117 MHz for a 1P-1P, between 119 MHz and 425 MHz for a 1P-2P qubit pair, 188 MHz-374 MHz for 1P-3P, and 120 MHz-732 MHz for 2P-2P. These ranges of ΔE_{Z} values are indicated in FIG. 9B. It is desirable for the ΔE_{Z} values to be as high as possible since they correspond to the highest achievable CNOT fidelities. To achieve these most advantageous ΔE_{Z} values, P atoms would have to be placed in the silicon crystal lattice with a perfect precision. In practice, it is challenging to deterministically fabricate qubits with specific donor configurations, as the incorporation of P atoms into the silicon crystal lattice has a statistical uncertainty of approximately ±1 lattice site that is intrinsic to the dissociative chemical processes that take place along the phosphorus donor atom incorporation pathway. It is determined that qubit pairs 1P-2P, 1P-3P and 2P-2P outperform single donors, regardless of the atomic configurations of the multi-donor qubits. Therefore, even with the fabrication uncertainty of ±1 lattice site, it is still beneficial to use multi-donor qubits since they allow for high CNOT fidelities to be reproducibly achieved. Assuming atomic precision of qubit fabrication, the 2P-2P becomes very attractive as it promises ΔE_{Z} as high as 732 MHz and the CNOT error as low as and 0.03%.

### Impact of Charge Noise on the CNOT Gate Fidelity

The impact of charge noise on the CNOT gate fidelity is investigated by varying the standard deviation of detuning noise σ_{ε} in the range 0.1-10 μeV. In FIG. 9C, the average CNOT gate error, achievable with 1P-1P, 1P-2P, 1P-3P and 2P-3P qubit pairs is depicted, as a function of charge noise σ_{ε} calculated for a fixed gate time of T_{CNOT}=2 us and magnetic noise of σ_{B}=2 kHz. For each qubit pair, the best case atomic arrangement is assumed (i.e., the arrangement that corresponds to the highest ΔE_{Z}). The line traces represent the highest achievable values for different donor numbers. As expected, a reduction in the gate error is observed for lower charge noise and larger ΔE_{Z} values. Interestingly, the larger the ΔE_{Z} value, the stronger the impact of charge noise. For instance, the decrease in charge noise from 100 μeV to 0.1 μeV results in a ˜10-fold improvement in case of 2P-3P, and only a 3-fold improvement for the 1P-1P. This is because for 1P-1P, the fidelity is predominantly limited by the quantum state leakage error, which is significantly larger than the errors that arise from charge noise. On the contrary, for the 2P-3P the CNOT gate performance is more dependent on charge noise since the state leakage error is much smaller and the dominating error source for the 2P-3P is the charge noise. All calculations assume a tunnel coupling of t_{c}=4 GHz between the qubits.

The impact of charge noise can be mitigated by increasing the t_{c}, which would effectively lower the fluctuations in J. However, with the t_{c} being too large it might be challenging to turn J completely off, as needed for independent spin measurements, since this will then require a large amplitude of detuning pulse. The optimal tunnel coupling depends therefore on available detuning voltage range, which can be limited either by device leakage or by pulse amplitude of the control instrumentation. In practice, the most optimal set of experimental parameters used for a CNOT gate needs to be tailored for a specific device.

Importantly, the large value of ΔE_{Z} not only reduces the errors associated with the leakage out of the computational basis, but also helps to minimize other types or gate errors. The CROT gate errors can be divided into five main categories as discussed below.

A first source of error comes from unwanted driving of the target qubit when the control qubit is in a |↓ [symbol] state. This error is associated with large negative ϵ values for which the target qubit ESR frequencies f_{↓}^{L} and f_{↑}^{L} are not well separated. This error can be reduced by increasing J. A second source of error may be unwanted driving of the control qubit. The ideal CNOT gate assumes that control qubit remains unchanged during the gate operation. However, at detuning values approaching zero, the resonant frequencies of both qubits converge (branches f_{↓}^{L} and f_{↑}^{R}). Thus, when applying an ESR pulse to perform a rotation of the target qubit, the control qubit might be inadvertently flipped. This error can be reduced by decreasing J. A third source of error may come from leakage out of the computational basis. After the CNOT operation, both electron spins are measured which corresponds to the projection from the {↓↓, [symbol] ↑↑} basis onto the computational basis {↓↓, ↓↑, ↑↓, ↑↑}. This leakage error is proportional to the θ=arctan (J/ΔE_{Z}). This error can be reduced by decreasing J (decreasing ϵ) and/or increasing ΔE_{Z}. A fourth source of error may be introduced in the dephasing process. Due to fluctuating of the surrounding nuclear spin bath, the amplitude of Rabi oscillations decay over time and limit the CNOT gate fidelity. This error can be reduced by shortening the gate time T_{CNOT}, or extending T*₂ with silicon purification methods that remove spinful ²⁹Si nuclei. A fifth source or error may be introduced because of charge noise. The fluctuations in detuning (ϵ) result in the target qubit being de-tuned from its resonance, hence the Rabi frequency of the target qubit varies throughout the CNOT gate and leads to dephasing. This error can be reduced by decreasing ϵ, since charge noise has been shown to be proportional to ϑJ/ϑϵ. The impact of charge noise can be also reduced by shortening the two-qubit gate time.

Importantly, the numerical model includes the combined effect of all the above-mentioned error sources. The decrease of the CNOT gate errors with an increase of ΔE_{Z} can be attributed to the interplay of different mechanisms mentioned above.

### SWAP and \sqrt{SWAP} Gates

As described previously, a SWAP gate swaps the states of the two qubits involved in the operation. For example, if the left qubit 312 has a value of 0 and the right qubit 314 has a value of 1, the SWAP gate operation should swap these values such that at the end of the operation the left qubit 312 has a value of 1 and the right qubit 314 has a value of 0. This section describes the impact of donor nuclear spin orientations on the exchange SWAP oscillations between multi-donor qubits.

For an electron spin qubit hosted on N phosphorus atoms, the qubit energy can be written as,

$$E = g {μ}_{B} {B}_{0} + {\sum }_{i = 1}^{N} {〈 {I}_{Z} 〉}_{i} {A}_{i} \qquad ( 16 )$$

where g is Lande g-factor, μ_{B} is the Bohr magneton, B₀ is the global magnetic field, [symbol] I_{Z} [symbol] ᵢ is the expectation value of the nuclear spin operator of the i-th donor and is ±½, and Aᵢ is the hyperfine coupling between the electron spin and the nuclear spin of an i-th donor nuclear spin. Small (≤10 MHz) qubit-to-qubit variations in the Zeeman term gμ_{B}B₀ are expected due to the non-homogeneities in the global magnetic field B₀, as well as variations in g-factor due to the local electric fields. These variations in the Zeeman energies, however, are much smaller than variations in the hyperfine coupling, A, which can take values between ˜10 MHz and ˜370 MHz depending on the exact atomic qubit arrangement. Thus, in donor-based devices, ΔE_{Z}, arises mainly from unequal hyperfine interactions on each qubit and can be approximated as shown in equation 9. Importantly, each time a nuclear spin of the k-th donor within a qubit is flipped, the operator [symbol] I_{Z} [symbol] ᵢ reverses its polarity (from ½ to −½ or the other way around) and consequently the ΔE_{Z} value changes by Aₖ.

### Multi-Donor Qubit System

For multi-donor qubit systems, ΔE_{Z} values can be calculated using Eq. 9. This is demonstrated below using a 3P-2P two-qubit system. With a total of five P atoms and two possible orientations of each nuclear spin ( [symbol] or [symbol] ) there are 2⁵=32 possible configurations of nuclear spins. To illustrate this, FIG. 10 shows some of these 32 configurations as well as the corresponding ΔE_{Z} values for the atomic donor atom arrangements indicated with rectangles in FIGS. 10A and 10B. In particular, each rectangular 2×6 grid in FIGS. 10A and 10B represents the crystal lattice on the (001) silicon plane, within which the device was patterned. The coloured circles show the donor positions within a qubit and the corresponding hyperfine values of the nuclear spins of the donor atoms with the unpaired electron in the dot, A^{3P}={50, 271, 311} MHz and A^{2P}={142, 142} MHz are given for each donor.

FIG. 10C shows the ΔE_{Z} values arising from the different orientations of nuclear spins for a two-qubit 3P-2P system, some of which are schematically shown. As an example, this figure shows the ΔE_{Z} values calculated for the atomic donor atom arrangements marked with red and blue rectangles in FIGS. 10A and 10B. In FIG. 10D the ΔE_{Z} parameter is plotted for all 32 cases. The same data is shown in the form of a histogram in FIG. 10E. The ΔE_{Z} value varies from 5 MHz for the nuclear spin configurations [symbol] , [symbol] , [symbol] [symbol] and [symbol] to 458 MHZ for [symbol] and [symbol] .

It is important to note that ΔE_{Z} is defined by the absolute value of the hyperfine energy difference (see Eq. 9). Hence, the two opposite configurations such as [symbol] and [symbol] yield the same magnitude of ΔE_{Z}. Additionally, the same value of ΔE_{Z} is shared between some configurations, for example [symbol] , [symbol] , due to the degeneracy of the [symbol] and [symbol] states. In total, amongst the 32 configurations there are 12 different ΔE_{Z} values.

This means that when the nuclear spin of one of the qubit-hosting P atoms flips, for instance due to relaxation processes, the ΔE_{Z} value can radically change (by tens or hundreds of MHz). Therefore, if the lifetime of a nuclear spin (typically ≥40 ms) is shorter than the time-scale of the experiment (typically several hours), the nuclear spin flips will effectively result in the quantised jumps in the ΔE_{Z} value during the experiment. Hence, during a long-running measurement, the switching value of ΔE_{Z} will produce a number of oscillation frequencies Ω=\sqrt{J²+ΔE_{z}²}, giving rise to a beating effect.

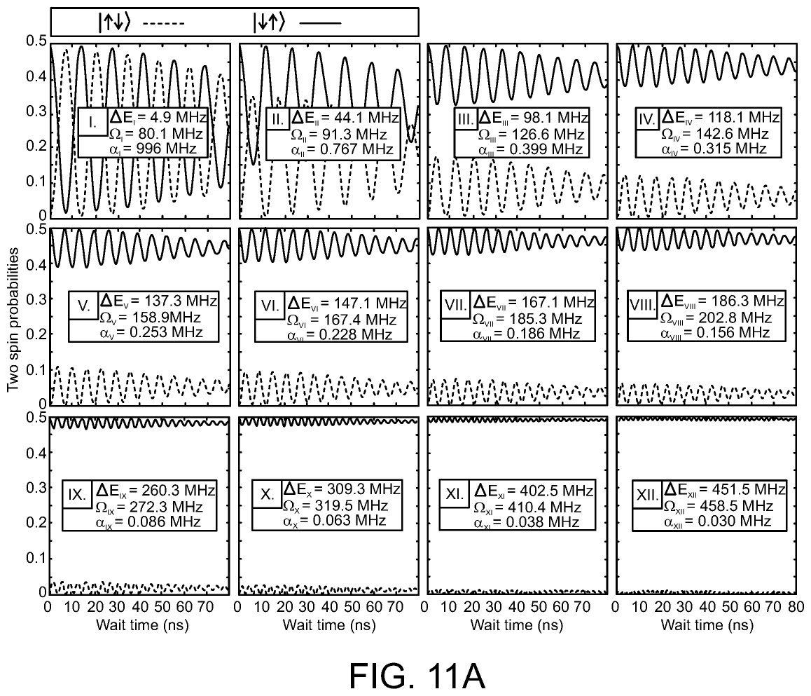

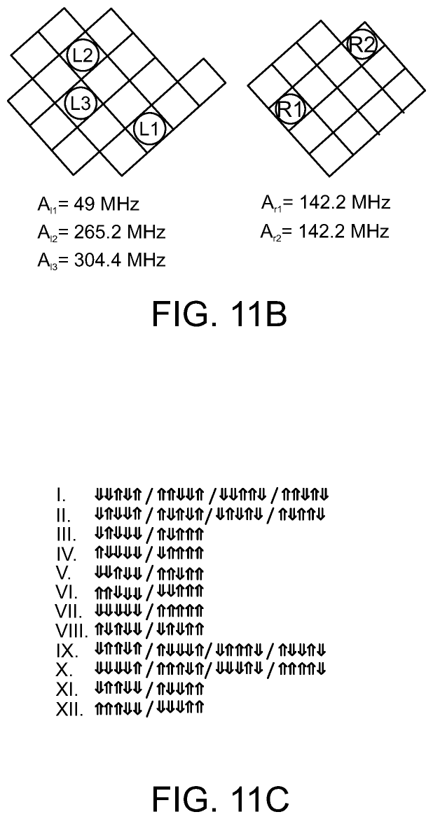

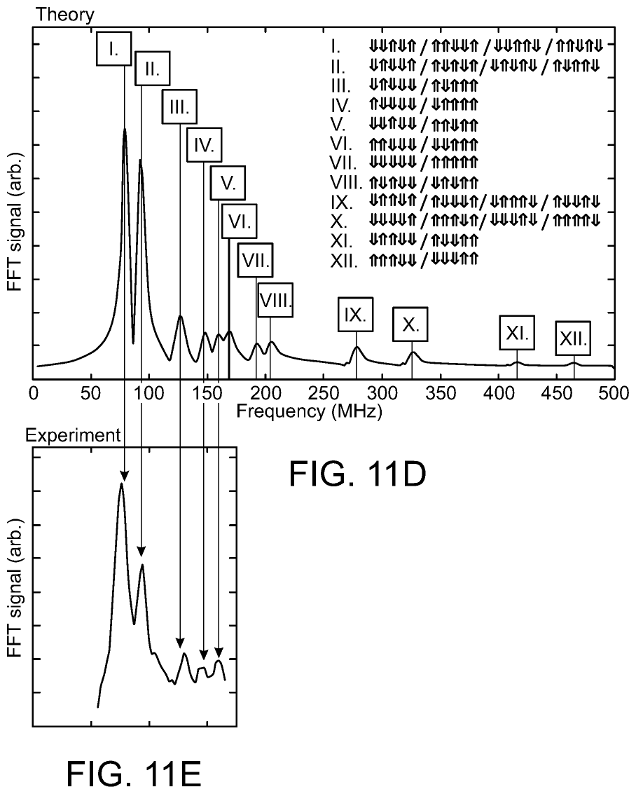

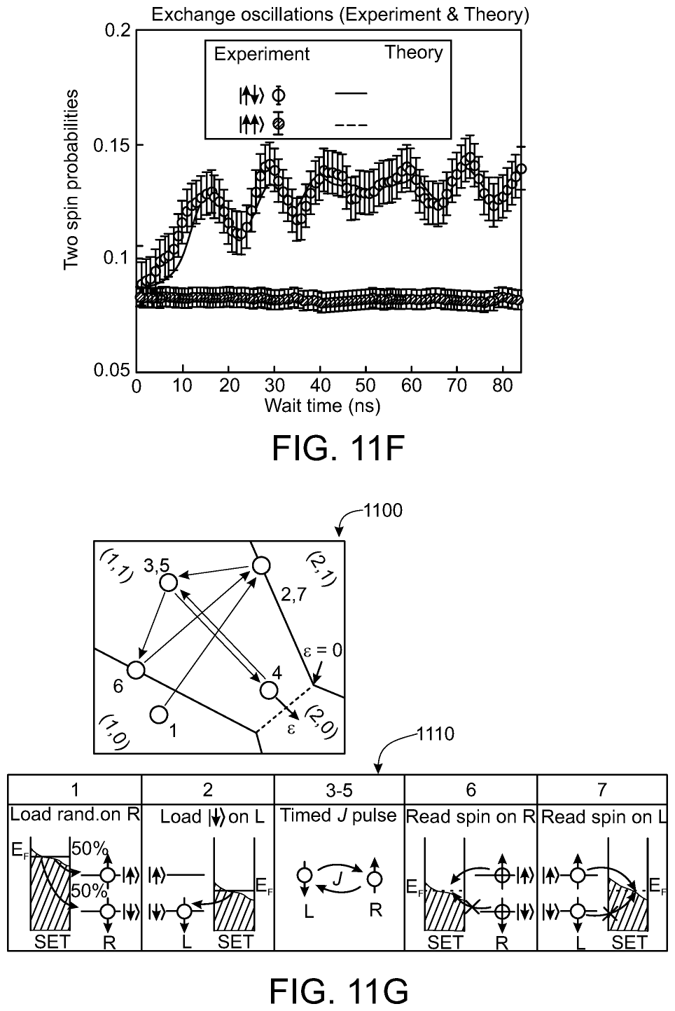

FIG. 11 shows the comparison between experiments and the theory of the beating effect, where the experimental data is obtained using pulse sequence as shown in FIG. 11G. In particular, 11G shows two schematics of the pulse sequence—one schematic 1100 depicts the pulse sequence used to measure exchange oscillations where the numbers in brackets indicate the number of electrons in qubit L and qubit R, respectively, the experiments are performed near the (1,1) to (2,0) inter-dot transition. The second schematic 1110 depicts the pulse sequence in the form of a timeline along with the energy levels of the left qubit L and the right qubit R relative to the SET Fermi energy during each step of the protocol. In particular, the pulse protocol shown in FIG. 11G includes seven steps: 1) loading a random spin on the right qubit R: 2) loading a spin-down state on the left qubit L: 3-5) performing a timed exchange pulse along the inter-dot detuning axis: 6) performing a single-shot readout of the electron spin on the right qubit R; and 7) performing a single-shot readout of the electron spin on the left qubit L.

The theoretical traces in FIG. 11 are calculated based on the time-evolution of a two-electron spin Hamiltonian in the |S [symbol] and |T₀ [symbol] basis—

$$H = ( \begin{matrix}J & Δ {E}_{Z} \\ Δ {E}_{Z} & 0\end{matrix} )$$

where the exchange energy J depends on the detuning energy between the left and right qubits L and R and is well approximated with the Hubbard model using equation—

$$J ( {t}_{c} , ϵ ) = \frac{ϵ}{2} + \sqrt{\frac{{ϵ}^{2}}{4} + {t}_{c}^{2}}$$

where t_{c} is the inter-dot tunnel coupling, defined as t_{c}≡J(ϵ=0). tc is assumed to be =1.8±0.1 GHz.

The exchange oscillations are modelled between the |↓↑ [symbol] and |↑↓ [symbol] states, for the 12 different ΔE_{Z} values possible for a 3P-2P system, as shown in sub-plots I-XII in FIG. 11A. For each of the twelve cases, the oscillation frequency, Ω, as well as the oscillation visibility α is provided. In particular, FIG. 11A shows plots of theoretically modelled exchange oscillations (J=80 MHz) between two electron spins hosted on 3P and 2P donor dots. The configuration of the donor atoms in the dots and their corresponding hyperfine values used in this experiment are depicted in FIG. 11B. With this configuration, the hyperfine values of the left dot were A^{3P}={49, 265.2, 304.4} MHz and the hyperfine values of the right dot were A^{2P}={142.2, 142.2} MHz. These particular hyperfine fields were chosen to best match the experimental results shown in FIGS. 11E and 11F. FIG. 11C shows the nuclear spin configurations that result in the 12 distinct ΔE_{Z} values. The first three spin orientations in each nuclear orientation shown in FIG. 11C corresponds to the nuclear spin orientations of the 3 donor atoms in the left dot and the last two spin orientations in each nuclear orientation shown in FIG. 11C corresponds to the nuclear spin orientations of the 2 donor atoms in the right dot.

The 12 cases shown in FIGS. 11A and 11C correspond to different values of ΔE_{Z} that are possible with a 3P-2P system, taken different configurations of nuclear spins. As ΔE_{Z} becomes larger (from I to XII), the effective oscillation frequency Ω is increased, and the oscillation amplitude α is reduced. This means that the visibility is large (α≈1) when the two electron spins are in the singlet-triplet basis, and small when the two electron spins are isolated. For a fixed magnitude of the exchange energy (J=80 MHz in this case), the oscillation frequency varies dramatically for different nuclear spin configurations, from Ω₁=80.1 MHz to Ω_{XII}=458.5 MHz. At the same time, the visibility of exchange oscillations ranges from α_{I}≈1 to α_{XII}≈0.

To account for all possible nuclear spin configurations, the theoretically modelled fast Fourier transform (FFT) signal of the |↓↑ [symbol] probability that oscillates with 12 discrete frequency components is plotted in FIG. 11D. The FFT peaks occur at frequencies corresponding to Ω₁-Ω_{XII} values. The twelve peaks in the FFT spectrum, labelled I-XII, correspond to the values listed in FIG. 11A. For each FFT peak, the underlying nuclear spin configurations are also provided. The FFT peak-widths are determined by the charge noise acting on J, and magnetic noise from the ²⁹Si nuclear spin bath, resulting in fluctuations in ΔE_{Z}. We find that the theoretically modelled FFT spectrum (FIG. 11D) is in good agreement with the plot shown in FIG. 11E, which shows experimental FFT spectrum data of the exchange oscillations, where the discrete oscillation frequencies can be clearly distinguished. In particular, the experimental spectrum confirms the presence of multiple discrete ΔE_{Z} values arising from the nuclear spin dynamics. We find that the exchange oscillations are dominated by the spectral components I and II, for which ΔE_{Z}<J, hence the highest visibility (see Eq. 5) and the strongest FFT signal. While the peaks I-V are observed in the experimental data, the higher-frequency peaks are characterised by low visibility and are not resolved within the noise floor of the experiment.

Lastly, in FIG. 11F the theory model is compared with the experimental data in the time domain. Here, the open-circle markers correspond to the same experimental data as in FIG. 11C, and the solid lines correspond to modelled data from FIG. 11B. From the time domain data one can clearly observe the beating effect arising from discrete switching of oscillation frequency (originating from the nuclear spin flips). In both frequency and time domain we find good agreement between the experiment and the theory, suggesting that the hyperfine values used in the modelling are good approximations of the actual values in the device.

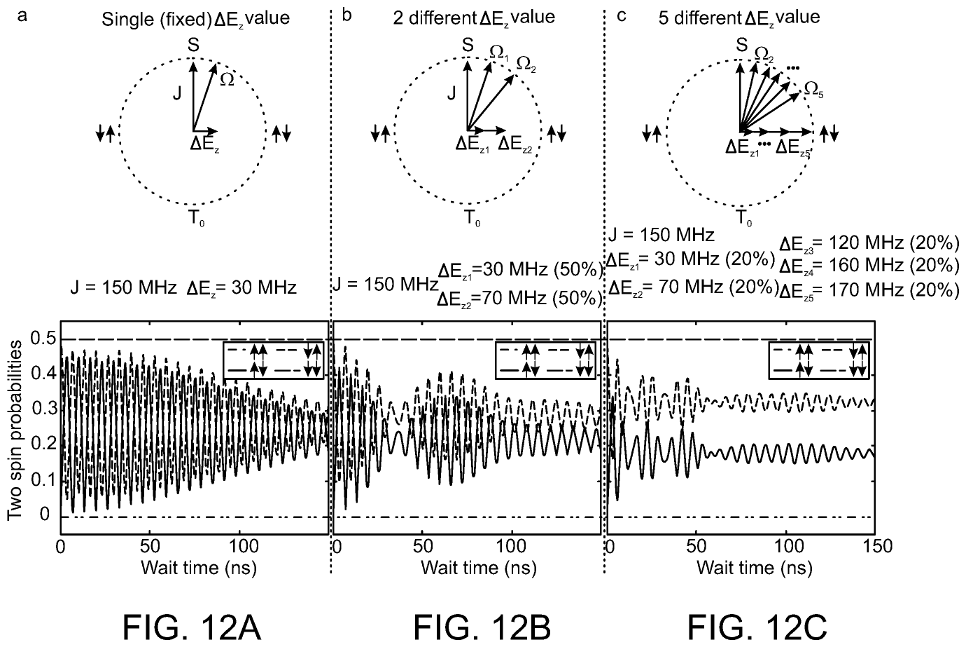

FIG. 12 shows the two-spin probabilities: |↓↓ [symbol] , |↓↑ [symbol] , |↑↓ [symbol] , and |↑↑ [symbol] , simulated for three different sets of ΔE_{Z} values (FIGS. 12A-12C). For FIGS. 12A-12C, the exchange energy is assumed to be J=150 MHz and the detuning noise is assumed to be σ_{ε}=5 μeV, in line with reported noise values in silicon. Further, all cases assume that a |↓ [symbol] state is initialized on the left qubit 312 and a random spin state on the right qubit 314. The exchange interaction acts on the |↓↑ [symbol] , |↑↓ [symbol] states during the J pulse, while the |↓↓ [symbol] , |↑↑ [symbol] , states remain unaffected.

The top panels in FIG. 12 show a schematic Bloch sphere that corresponds to the given case. In the first case (FIG. 12A), a fixed value of ΔE_{Z}=30 MHz is considered, which results in standard oscillations between the |↓↑ [symbol] and |↑↓ [symbol] , population. Here, the oscillations can be described by a product of sinusoidal drive with a frequency=Ω=\sqrt{ΔE_{z}²+J²} and a Gaussian decay function due to dephasing. The second case (FIG. 12B) assumes two equally probable values of Zeeman energy difference −ΔE_{Z1}=30 MHz and ΔE_{Z2}=70 MHz. In such a scenario, a beating is observed with the envelope frequency of,

$${f}_{beat} = ℏ \vert \frac{{Ω}_{2} - {Ω}_{1}}{2} \vert = ℏ \vert \frac{\sqrt{Δ {E}_{Z 2}^{2} + {J}^{2}} - \sqrt{Δ {E}_{Z 1}^{2} + {J}^{2}}}{2} \vert \qquad ( 17 )$$

where ℏ is the reduced Planck's constant. In this particular case the beating frequency, f_{beat}=6.2 MHz, corresponds to the envelope period of T_{beat}=1/f_{beat}=159.25 ns. Thus, as seen in FIG. 10B, the first node of the beating envelope is observed at T_{beat}/4=39.8 ns.

Next, a case where ΔE_{Z} switches at random between 5 discrete values −ΔE_{Z}∈(30, 70, 120, 160, 170) MHz (see FIG. 12C). The resulting coherent oscillations are now modulated with multiple beating frequencies, which gives rise to rather complex functions describing the |↓↑ [symbol] and |↑↓ [symbol] populations. Importantly, the visibility of coherent oscillations is reduced when ΔE_{Z} switches between different values, due to the overlapping beating envelopes. Consequently, the fidelity of the two-qubit \sqrt{SWAP} gate is decreased. This effect is particularly visible for the case presented in FIG. 12C, where the |↓↑ [symbol] and |↑↓ [symbol] populations barely cross each other. This indicates poor fidelity of the SWAP and \sqrt{SWAP} gates since the |↓↑ [symbol] and |↑↓ [symbol] populations are not completely ‘swapping’. Therefore, it is desirable to minimise the number of frequency components and their spread during the two-qubit SWAP and \sqrt{SWAP} operations.

Having shown the impact of nuclear spin dynamics on the exchange-based oscillations, its implications for two-qubit gate fidelities are now discussed. The ΔE_{Z} switching between several discrete values results in lowering of the visibility of the SWAP oscillations, where |↓↑ [symbol] and |↑↓ [symbol] probabilities do not cross-over, or swap, hence limiting SWAP and \sqrt{SWAP} gate fidelities. This effect can be mitigated by increasing the number of electrons on donor sites and using the spin of the outermost electron as a qubit. As more electrons are added, the electron wave-functions become larger and the A coupling is reduced. Consequently, the outer electrons are ‘shielded’ from the nuclear fields and the exchange-based two-qubit operations are substantially immune to the nuclear spin flips.

Electron shielding was experimentally employed to achieve two-qubit \sqrt{SWAP} gate. In the experiment, the two-dot device 300 was operated with a total of four electrons, one electron on the left dot 302 and three electrons on the right dot 304. The first two electrons on the right dot 304 formed a singlet state and provided screening between the nuclear spin states and the third electron that effectively narrowed down the spread of possible ΔE_{Z}. In fact, spectroscopic experiments on the device confirmed that the spread of ΔE_{Z} values in a device with electron shielding, the ΔE_{Z}∈(85, 121) MHz, which is much smaller than for an unshielded device where ΔE_{Z}∈(5, 458) MHz. Therefore, by comparing the SWAP oscillations from two separate donor devices, it is seen that qubits operated with higher electron numbers are less sensitive to nuclear spin flips and hence are better suited for two-qubit \sqrt{SWAP} and SWAP gates between electron spins.

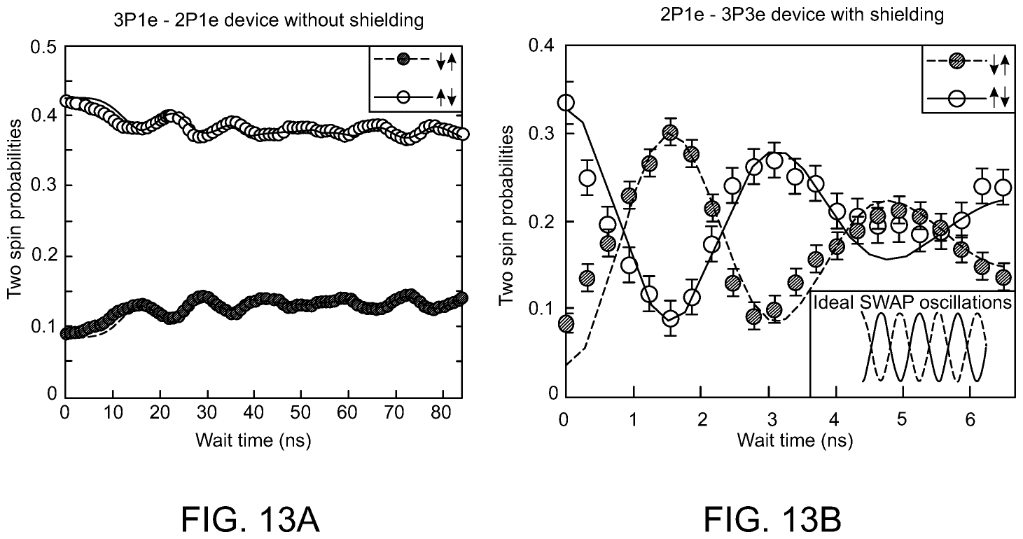

To illustrate the importance of this electron shielding for the two-qubit \sqrt{SWAP} and SWAP gates, in FIG. 13 the SWAP oscillations obtained on two separate devices. In particular, FIG. 13A shows the SWAP oscillations for an unshielded 3P-2P device operated with one electron per dot and FIG. 13B shows the SWAP oscillations for a shielded device operated with one and three electrons on the left and right dots, respectively. Since both qubits in the device of FIG. 13A are operated with a single electron (1e), the hyperfine values are relatively large and, consequently, there are large variations in ΔE_{Z} due to nuclear spin flips. Since 75% of the time the system in in the ΔE_{Z}>J regime, the visibility of exchange SWAP oscillations is reduced to ˜0.05, so that the |↓↑ [symbol] and |↑↓ [symbol] states do not cross-over as required for the \sqrt{SWAP} and SWAP gates. In the device in FIG. 13B, the first two electrons on the right qubit form a magnetically inactive singlet state and provide charge shielding between the third electron and the nuclear spins. Thus, the wavefunction of the third electron is larger, which makes the hyperfine coupling smaller, and the two-qubit system is less sensitive to nuclear spin dynamics. Because of the shielding of the right 3P3e qubit, the condition ΔE_{Z}<J is always satisfied, leading to the relatively large visibility (˜0.3) of exchange SWAP oscillations.

As an alternative to electron shielding, fidelities of two-qubit SWAP and \sqrt{SWAP} gates can be improved by controlling the nuclear spin orientations. For a given pair of donor qubits, one should consider the number of ΔE_{Z} values that arise from different nuclear spin configurations. Prior to executing a two-qubit gate, the nuclear spins should be then prepared in a configuration for which ΔE_{Z}<<J. For example, a 3P-2P qubit pair has 32 possible nuclear spin configurations as schematically shown in FIG. 11C. In this particular example, there are 12 discrete values that ΔE_{Z} can take, and the corresponding SWAP oscillations for these 12 ΔE_{Z} values are simulated and are shown in FIG. 11A. The highest visibility of the SWAP oscillations, as well as the highest SWAP and \sqrt{SWAP} gate fidelities, are found for the smallest possible ΔE_{Z} value. In the example shown in FIG. 11A, the smallest ΔE_{Z} is 4.9 MHz, which corresponds to nuclear spin configurations [symbol] , [symbol] , [symbol] [symbol] and [symbol] . Therefore, to maximize the SWAP and \sqrt{SWAP} gate fidelities, the nuclear spins should be prepared in one of these configurations, which can be achieved with NMR by applying AC magnetic fields at frequencies corresponding to a given nuclear spin.

### Optimal Nuclear Spin Orientations for Different Logical Operations

The optimal orientation of nuclear spins for two-qubit gates depends on the hyperfine couplings as well as the two-qubit gate type. Here we use examples of 1P-2P and 2P-3P qubit pairs to explain how these optimal nuclear spin orientations can be found.

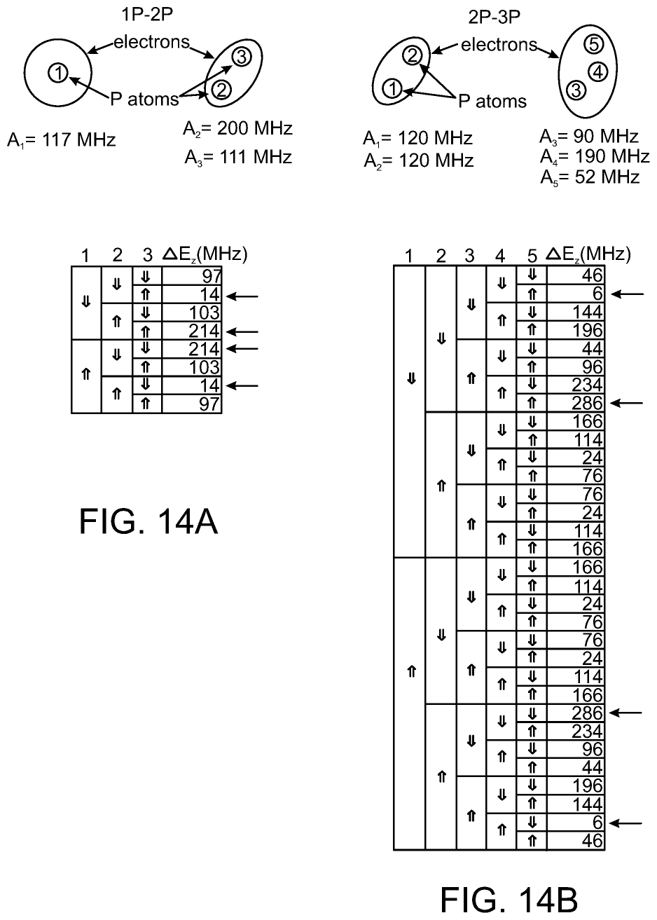

FIG. 14A shows a schematic of a 1P-2P qubit pair, where the respective hyperfine couplings for the three donor nuclear spins in the qubit pair are A₁=117 MHZ, A₂=200 MHz, and A₃=111 MHz. Next, all 8 possible configurations of the donor nuclear spins are considered, and the corresponding ΔE_{Z} values are shown in the Table in FIG. 14A. It is determined from this table that a minimum ΔE_{Z} of 14 MHz can be achieved when nuclear spins labeled as 1, 2, 3 are initialized [symbol] or [symbol] , respectively. Similarly, we find that a maximum ΔE_{Z} of 214 MHz can be achieved when nuclear spins within the two dots are antiparallel, that is when the nuclear spin 1, 2, 3 are initialized [symbol] or [symbol] , respectively.

Analogously, FIG. 14B shows a schematic of a 2P-3P qubit pair, where the five donor nuclear spins are labeled from 1 to 5. The hyperfine couplings in this system are A₁=120 MHz, A₂=120 MHz, A₃=90 MHz, A₄=190 MHz, A₅=52 MHz. The table in FIG. 14B shows all 32 possible nuclear spin configurations, together with the corresponding ΔE_{Z} spanning from 6 MHz to 286 MHz. The smallest ΔE_{Z} of 6 MHz corresponds to the [symbol] or [symbol] nuclear spin configurations. The largest ΔE_{Z} of 286 MHz corresponds to the antiparallel [symbol] or [symbol] nuclear spin configurations.

For both examples shown, the nuclear spins configurations most suitable for performing SWAP and \sqrt{SWAP} two-qubit gates are indicated with green arrows. These configurations correspond to the smallest ΔE_{Z} for each system. The nuclear spins configurations most suitable for performing CROT and CPHASE two-qubit gates are indicated with purple arrows. These configurations correspond to the largest ΔE_{Z} for each system.

Although the aspects of the present disclosure are described with respect to SWAP and \sqrt{SWAP} gates. They can be generally implemented to SWAP^{α} gates where a is any value between 0-4π.

The term “comprising” (and its grammatical variations) as used herein are used in the inclusive sense of “having” or “including” and not in the sense of “consisting only of”.

It will be appreciated by persons skilled in the art that numerous variations and/or modifications may be made to the invention as shown in the specific embodiments without departing from the spirit or scope of the invention as broadly described. The present embodiments are, therefore, to be considered in all respects as illustrative and not restrictive.

1. A method of operation of a quantum processing element, the quantum processing element comprising:
a semiconductor,
a dielectric material forming an interface with the semiconductor,
a plurality of dopant dots embedded in the semiconductor, each of the dopant dots comprising one or more dopant atoms and one or more electrons or holes confined within the dopant dots, wherein spin of an unpaired electron or hole of each dopant dot forms at least one qubit;
the method comprising the step of:
controlling orientation of nuclear spins of the one or more dopant atoms in a pair of dopant dots and/or controlling a hyperfine interaction between nuclear spins of one or more dopant atoms and electron or hole spins of the unpaired electron or hole in the pair of dopant dots to perform a quantum logic operation on a corresponding pair of qubits.

2. The method of claim 1, wherein at least one of the dopant dots in the pair of the dopant dots includes multiple donor or acceptor atoms.

3. The method of any one of claims 1-2, wherein at least one of the dopant dots in the pair of the dopant dots includes multiple electrons or holes.

4. The method of any one of claims 1-3, wherein controlling the hyperfine interaction includes at least one of: changing a number of dopant atoms in the dopant dots, arranging the dopant atoms within a dopant dot, controlling the number of electrons or holes in a dopant dot, controlling the background electrical field applied to the quantum processing element.

5. The method of any one of claims 1-3, wherein the pair of the qubits are used to perform a controlled ROT (CROT) gate and a controlled PHASE (CPHASE) gate and wherein controlling the orientation of the nuclear spins of the one or more dopant atoms in the pair of dopant dots comprising maximizing the energy difference between the qubits.

6. The method of claim 5, wherein to maximize the energy difference between the qubits for CROT and CPHASE gates, the nuclear spins in one dopant dot are oriented anti-parallel to the nuclear spins in the other dopant dot of the pair of dopant dots.

7. The method of claim 5, wherein to maximize the energy difference between the qubits, at least one of the pair of dopant dots includes a plurality of dopant atoms, and the plurality of dopant atoms are positioned within the corresponding dopant dot such that the probability density of the wavefunction of the confined electrons or holes at these atomic sites is maximized.

8. The method of any one of claims 1-4, wherein the pair of the qubits are used to perform a controlled ROT (CROT) gate and a controlled PHASE (CPHASE) gate and wherein controlling the hyperfine interaction comprising controlling the hyperfine interaction such that the energy difference between the qubits is maximized.

9. The method of claim 8, wherein controlling the hyperfine interaction such that the energy difference between the pair of qubits is maximized includes shielding the nuclear spins of the pair of dopant dots by adding multiple electrons or holes to each of the pair of dopant dots.

10. The method of any one of claims 1-3, wherein the pair of dopant dots are used to perform a SWAP^{α} gate, where α is between 0-4π and wherein controlling the orientation of the nuclear spins of the one or more dopant atoms in the pair of dopant dots comprising minimizing the energy difference between the qubits.

11. The method of any one of claims 1-3, wherein different gate operations can be performed on the pair of qubits by dynamically controlling the nuclear spins to create an optimal energy difference between the pair of qubits.

12. A quantum processing element comprising:
a semiconductor,
a dielectric material forming an interface with the semiconductor,
a plurality of dopant dots embedded in the semiconductor, each dopant dot comprising one or more donor or acceptor atoms and one or more electrons or holes confined within the corresponding dopant dots, wherein spin of an unpaired electron or hole of each of the dopant dots forms a qubit,
wherein to perform a quantum logic operation between at least a pair of the qubits, an orientation of nuclear spins of the one or more dopant atoms in the at least pair of dopant dots is controlled.

13. The quantum processing element of claim 12, wherein at least one of the dopant dots in the pair of the dopant dots includes multiple donor or acceptor atoms.

14. The quantum processing element of any one of claims 12-13, wherein at least one of the dopant dots in the pair of the dopant dots includes multiple electrons or holes.

15. The quantum processing element of any one of claims 12-14 where the donor atoms as phosphorus atoms.

16. The quantum processing element of claims 12-15, wherein the pair of the qubits are used to perform a controlled ROT (CROT) gate and a controlled PHASE (CPHASE) gate and wherein controlling the orientation of the nuclear spins of the one or more dopant atoms in the pair of dopant dots comprising maximizing the energy difference between the qubits.

17. The quantum processing element of claims 12-15, wherein the pair of dopant dots are used to perform a SWAP^{α} gate, where α is between 0-4π and wherein controlling the orientation of the nuclear spins of the one or more dopant atoms in the pair of dopant dots comprising minimizing the energy difference between the qubits.

18. The quantum processing element of any one of claims 12-15, wherein the fidelity of the logic gate operation performed on the at least pair of qubits can be increased by controlling a hyperfine interaction between the nuclear spins of the one or more dopant atoms and electron or hole spins of the unpaired electron or hole in the at least pair of dopant dots.

19. The quantum processing element of claim 18, wherein controlling the hyperfine interaction includes at least one of: changing a number of dopant atoms in the dopant dots, arranging the dopant atoms within a dopant dot, controlling the number of electrons or holes in a dopant dot, controlling the background electrical field applied to the quantum processing element.

20. The quantum processing element of claim 19, wherein the hyperfine interaction is controlled to maximize the energy difference between the pair of qubits by shielding the nuclear spins of the pair of dopant dots and adding multiple electrons or holes to each of the pair of dopant dots.
